(19) United States
(12) Patent Application Publication
(10) Pub. No.: US 2010/0136795 A1
(43) Pub. Date: Jun. 3, 2010

(54) FILM DEPOSITION APPARATUS, FILM DEPOSITION METHOD, SEMICONDUCTOR DEVICE FABRICATION APPARATUS, SUSCEPTOR FOR USE IN THE SAME, AND COMPUTER READABLE STORAGE MEDIUM

(75) Inventor: MANABU HONMA, Oshu-Shi (JP)

Correspondence Address: IPUSA, P.L.L.C, 1054 31ST STREET, N.W., Suite 400, Washington, DC, 20007, US

(73) Assignee: TOKYO ELECTRON LIMITED

(21) Appl. No.: 12/618,880

(22) Filed: Nov. 16, 2009

(30) Foreign Application Priority Data
Nov. 28, 2008 (JP) 2008-305341

(51) Int. Cl. H01L 21/30; C23C 16/458

(52) U.S. Cl. 438/758; 118/728; 118/730; 257/E21.211

(57) ABSTRACT

A disclosed semiconductor device fabrication apparatus includes a chamber where a predetermined process is carried out with respect to a substrate; a transfer arm that includes claw portions for supporting a lower peripheral surface portion of the substrate and that moves into and out from the chamber; and a susceptor that includes a substrate receiving portion in which the substrate is placed, and a step portion provided to allow the claw portions to move to a position lower than an upper surface of the substrate receiving portion.

### CROSS-REFERENCE TO RELATED APPLICATION

This application claims the benefit of priority of Japanese Patent Application No. 2008-305341, filed on Nov. 28, 2008, with the Japanese Patent Office, the entire contents of which are hereby incorporated by reference.

### BACKGROUND OF THE INVENTION

1. Field of the Invention

The present invention relates to a film deposition apparatus, a film deposition method, a semiconductor device fabrication apparatus, a susceptor for use in the same, and a computer readable storage medium.

2. Description of the Related Art

In order to fabricate semiconductor devices, semiconductor device fabrication apparatuses including a film deposition apparatus, an etching apparatus, a thermal processing apparatus and the like are used. In these semiconductor device fabrication apparatuses, a semiconductor substrate (wafer) is placed in a susceptor provided in accordance with a type of the semiconductor device fabrication apparatus. For example, some film deposition apparatuses may employ a susceptor on which two to six wafers are laid out flat.

In such a susceptor, at least three lift pins are provided that can move upward/downward penetrating through the susceptor in a wafer receiving area, which makes it possible for the wafer to be placed on the susceptor. Specifically, the wafer is transferred to above the wafer receiving area by a transfer arm provided at the distal end with a wafer fork; the lift pins are raised to receive the wafer from the wafer fork; the transfer arm is pulled away; and the lift pins are lowered, so that the wafer is placed on the susceptor. Such lift pins that move through corresponding through holes are disclosed, for example, in U.S. Pat. No. 6,646,235 (FIGS. 2, 3).

### SUMMARY OF THE INVENTION

When the inventor of this invention investigated the susceptor configured above, it was revealed that the following disadvantages are caused from the through holes for the lift pins. Namely, when a purge gas may flow toward the lower surface of the susceptor to prevent a film from being deposited on the lower surface of the susceptor in the film deposition apparatus, if the purge gas flows through the through holes to the upper surface side of the susceptor, the wafer is pushed upward by the purge gas, if only slightly. When the wafer is pushed upward by the purge gas, the wafer may deviate from the wafer receiving area of the susceptor and may be thrown away from the susceptor when the susceptor is rotated. In addition, because contact becomes reduced between the wafer and the susceptor when the wafer is pushed upward, temperature uniformity across the wafer is degraded, so that film thickness and film properties of the film deposited on the wafer may be degraded accordingly. Moreover, portions of the wafer that correspond to the through holes for the lift pins may be cooled by the purge gas flowing upward through the through holes, which adversely affects the temperature uniformity across the wafer. Furthermore, when the purge gas flows from the lower side of the wafer into the gaseous phase (chamber atmosphere) around a wafer edge, source gas flows are disturbed. As a result, film thickness uniformity, composition of film constituent elements, surface morphology and the like of the film deposited on the wafer may be degraded. Specifically, when a gas flow pattern is disturbed in a Molecular Layer Deposition (MLD) (also referred to as Atomic Layer Deposition (ALD)), two or more source gases are intermixed in the gaseous phase, which may deteriorate the MLD.

The present invention has been made in view of the above, and provides a film deposition apparatus, a film deposition method, a semiconductor device fabrication apparatus, and a susceptor to be used for the apparatuses that are capable of preventing a problem caused when a substrate is placed by lift pins, and a computer readable storage medium that stores a computer program that causes the film deposition apparatus to perform the film deposition method.

A first aspect of the present invention provides a film deposition apparatus for depositing a film on a substrate by carrying out a cycle of alternately supplying at least two kinds of reaction gases that react with each other to the substrate to produce a layer of a reaction product in a chamber. The film deposition apparatus includes a transfer arm including a claw portion for supporting a lower peripheral surface portion of the substrate, wherein the transfer arm is movable into and out from the chamber; a susceptor rotatably provided in the chamber, wherein the susceptor includes a substrate receiving portion provided, in one surface of the susceptor, for the substrate to be placed in, and a step portion provided to allow the claw portion to move to a position lower than an upper surface of the substrate receiving portion; a first reaction gas supplying portion configured to supply a first reaction gas to the one surface; a second reaction gas supplying portion configured to supply a second reaction gas to the one surface, wherein the second reaction gas supplying portion is separated from the first reaction gas supplying portion along a rotation direction of the susceptor; a separation area located along the rotation direction between a first process area in which the first reaction gas is supplied and a second process area in which the second reaction gas is supplied; a center area that is located substantially in a center portion of the chamber in order to separate the first process area and the second process area, and has an ejection hole that ejects a first separation gas along the one surface; and an evacuation opening provided in the chamber in order to evacuate the chamber; wherein the separation area includes a separation gas supplying portion that supplies a second separation gas, and a ceiling surface that creates in relation to the one surface of the susceptor a thin space in which the second separation gas may flow from the separation area to the process area side in relation to the rotation direction.

A second aspect of the present invention provides a semiconductor device fabrication apparatus that includes a chamber where a predetermined process is carried out with respect to a substrate; a transfer arm that includes claw portions for supporting a lower peripheral surface portion of the substrate and that moves into and out from the chamber; and a susceptor that includes a substrate receiving portion in which the substrate is placed, and a step portion provided to allow the claw portions to move to a position lower than an upper surface of the substrate receiving portion.

A third aspect of the present invention provides a susceptor on which a substrate subject to a predetermined process is placed in a semiconductor device fabrication apparatus. The susceptor includes a substrate receiving portion on which the substrate is placed; and a step portion provided to allow a claw portion of a substrate transport arm to move to a position lower than an upper surface of the susceptor, the claw supporting a lower peripheral surface portion.

A fourth aspect of the present invention provides a film deposition method for depositing a film on a substrate by carrying out a cycle of alternately supplying at least two kinds of reaction gases that react with each other to the substrate to produce a layer of a reaction product in a chamber. The film deposition method includes steps of supporting a lower peripheral surface portion of the substrate with a claw portion provided in a transfer arm and transferring the substrate into the chamber with the transfer arm; placing the substrate on a susceptor by using a step portion of the susceptor to move the claw portion to a position lower than an upper surface of a substrate receiving portion, wherein the susceptor is rotatably provided in the chamber, and includes the substrate receiving portion, in one surface of the susceptor, for the substrate to be placed in, and the step portion is provided to allow the claw portion of the transfer arm to move to a position lower than the upper surface of the substrate receiving portion; rotating the susceptor on which the substrate is placed; supplying a first reaction gas from a first reaction gas supplying portion to the susceptor; supplying a second reaction gas from a second reaction gas supplying portion to the susceptor, the second reaction gas supplying portion being separated from the first reaction gas supplying portion along a rotation direction of the susceptor; supplying a first separation gas from a separation gas supplying portion provided in a separation area located between a first process area in which the first reaction gas is supplied from the first reaction gas supplying portion and a second process area in which the second reaction gas is supplied from the second reaction gas supplying portion, in order to flow the first separation gas from the separation area to the process area relative to the rotation direction of the susceptor in a thin space created between a ceiling surface of the separation area and the susceptor; supplying a second separation gas from an ejection hole formed in a center area located in a center portion of the chamber; and evacuating the chamber.

A fifth aspect of the present invention provides a computer readable storage medium storing a program for causing a film deposition apparatus according to the first aspect to perform a film deposition method according to the fourth aspect for depositing a film on a substrate by carrying out a cycle of alternately supplying at least two kinds of reaction gases that react with each other to the substrate to produce a layer of a reaction product in a chamber.

### BRIEF DESCRIPTION OF THE DRAWINGS

FIG. 1 schematically illustrates a film deposition apparatus according to an embodiment of the present invention;

FIG. 2 is a perspective view illustrating an inside of a chamber body of the film deposition apparatus of FIG. 1;

FIG. 3 is a plan view illustrating an inside of a chamber body of the film deposition apparatus of FIG. 1;

FIG. 4 illustrates a positional relationship among gas supplying nozzles, a susceptor, and a convex portion in the film deposition apparatus of FIG. 1;

FIG. 5 is a perspective view illustrating a part of an arm portion of the transfer arm in the film deposition apparatus of FIG. 1;

FIG. 6 is a partial cross-sectional view of the film deposition apparatus of FIG. 1;

FIG. 7 is a partial perspective view of the film deposition apparatus of FIG. 1;

FIG. 8 is a partial cross-sectional view of the film deposition apparatus of FIG. 1;

FIG. 9 is a partial perspective view illustrating the transfer arm accessing the chamber body of the film deposition apparatus of FIG. 1;

FIG. 10 is an explanatory view for explaining wafer transfer-in operations in the film deposition apparatus of FIG. 1;

FIG. 11 is an explanatory view for explaining operations of the transfer arm in the film deposition apparatus of FIG. 1;

FIG. 12 illustrates gas flow patterns of gases flowing in the chamber body of the film deposition apparatus of FIG. 1;

FIG. 13 is an explanatory view for explaining a shape of the convex portion of the film deposition apparatus of FIG. 1;

FIG. 14 illustrates a modification example of the gas supplying nozzle of the film deposition apparatus of FIG. 1;

FIG. 15 illustrates modification examples of the convex portion of the film deposition apparatus of FIG. 1;

FIG. 16 illustrates modification examples of the convex portion and the gas supplying nozzle of the film deposition apparatus of FIG. 1;

FIG. 17 illustrates other modification examples of the convex portion of the film deposition apparatus of FIG. 1;

FIG. 18 illustrates another layout of the gas supplying nozzles in the chamber body of the film deposition apparatus of FIG. 1;

FIG. 19 illustrates another modification example of the convex portion of the film deposition apparatus of FIG. 1;

FIG. 20 illustrates an example where the convex portions are provided for reaction gas supplying nozzles in the chamber body of the film deposition apparatus of FIG. 1;

FIG. 21 illustrates yet another modification example of the convex portion of the film deposition apparatus of FIG. 1;

FIG. 22 schematically illustrates a film deposition apparatus according to another embodiment of the present invention;

FIG. 23 illustrates a modification example of a susceptor of the film deposition apparatus of FIG. 1 or FIG. 22;

FIG. 24 is an explanatory view for explaining operations of wafer transfer-in procedures using the susceptor of FIG. 23;

FIG. 25 schematically illustrates a substrate processing apparatus according to the embodiments of the present invention, which includes the film deposition apparatus of FIG. 1 or 22;

FIG. 26 illustrates another modification example of the susceptor;

FIG. 27 illustrates a modification example of the transfer arm; and

FIG. 28 illustrates yet another modification example of the susceptor.

### DETAILED DESCRIPTION OF THE PREFERRED EMBODIMENT

According to an embodiment of the present invention, there are provided a film deposition apparatus, a film deposition method, a semiconductor device fabrication apparatus, and a susceptor to be used for the apparatuses that are capable of preventing a problem caused when a substrate is placed by lift pins, and a computer readable storage medium that stores a computer program that causes the film deposition apparatus to perform the film deposition method.

Referring to the accompanying drawings, a film deposition film according to an embodiment of the present invention is explained in the following.

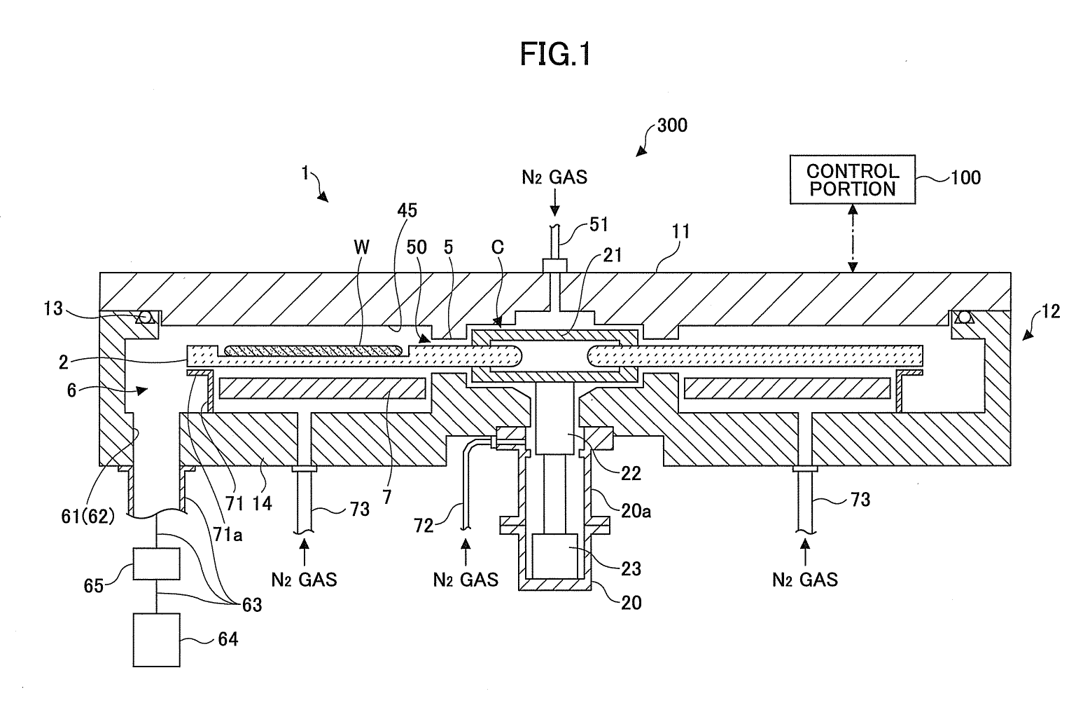

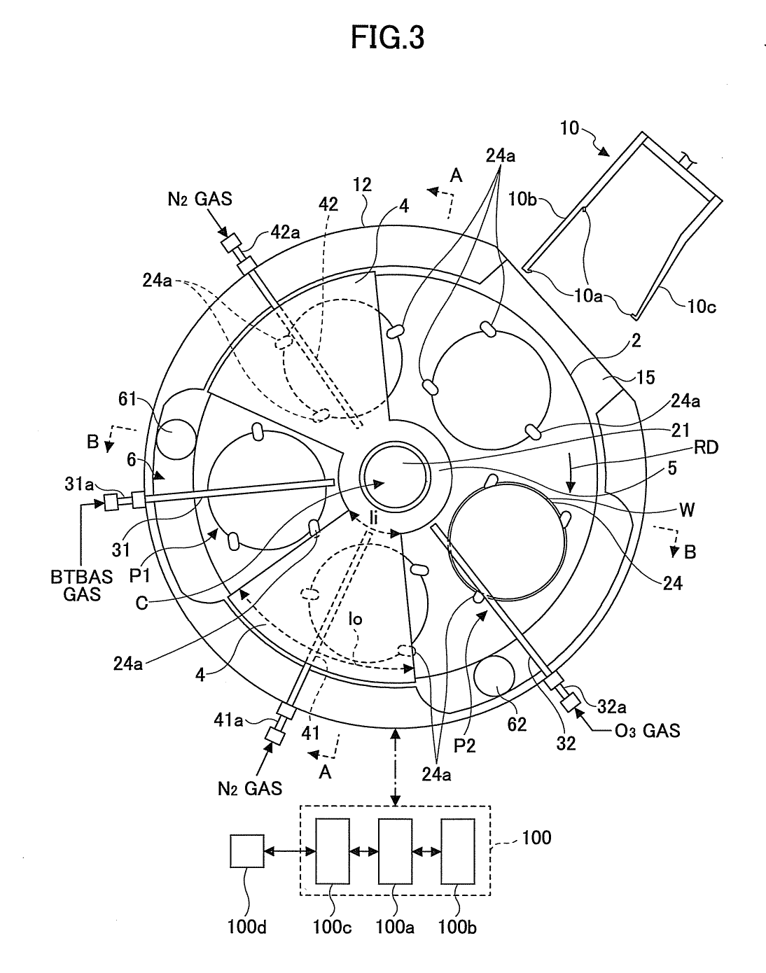

Referring to FIG. 1, which is a cross-sectional view taken along B-B line in FIG. 3, a film deposition apparatus 300 according to this embodiment of the present invention has a vacuum chamber 1 having a flattened cylinder shape, and a susceptor 2 that is located inside the vacuum chamber 1 and has a rotation center at a center of the vacuum chamber 1. The vacuum chamber 1 is made so that a ceiling plate 11 can be separated from a chamber body 12. The ceiling plate 11 is pressed onto the chamber body 12 via a sealing member 13 such as an O ring, so that the vacuum chamber 1 is hermetically sealed. On the other hand, the ceiling plate 11 can be raised by a driving mechanism (not shown) when the ceiling plate 11 has to be removed from the chamber body 12.

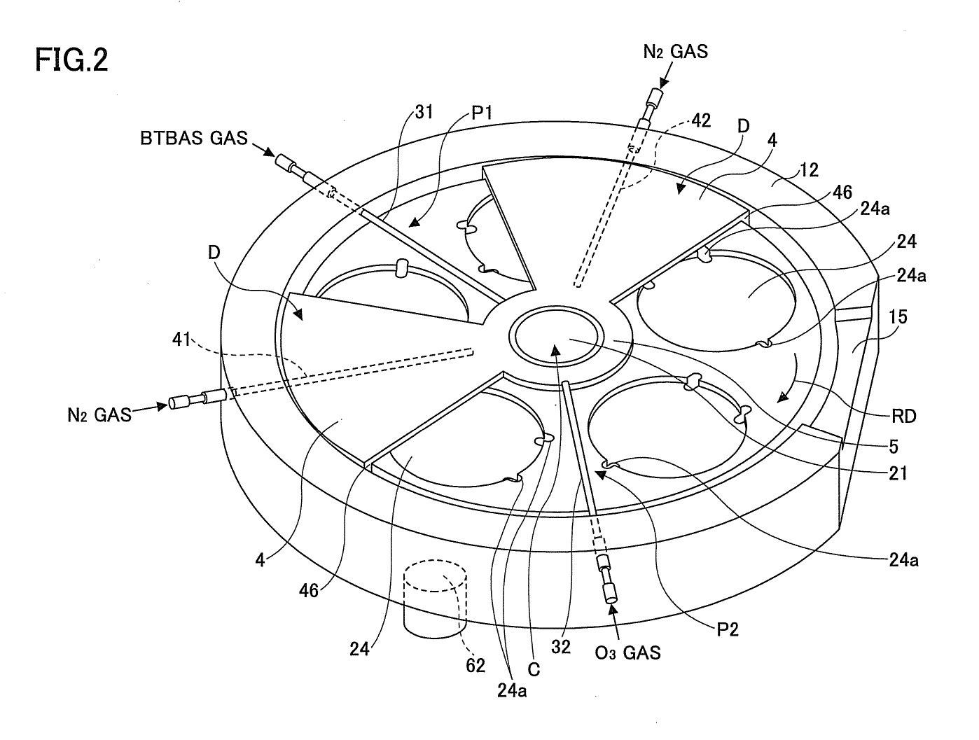

The susceptor 2 is made of a carbon plate having a thickness of about 20 mm in this embodiment and has a shape of a circular plate having a diameter of about 960 mm. An upper surface, a lower surface, and a side surface of the susceptor 2 may be coated with silicon carbide (SiC). As shown in FIG. 1, the susceptor 2 has an opening in the center and is supported such that a core portion 21 sandwiches the susceptor 2 around the opening. The core portion 21 is fixed on a top end of a rotational shaft 22 that extends in a vertical direction. The rotational shaft 22 penetrates a bottom portion 14 of the chamber body 12 and is fixed at the lower end to a driving mechanism 23 that can rotate the rotational shaft 22 around a vertical axis (for example, in a rotation direction RD shown in FIG. 2) in this embodiment. The rotational shaft 22 and the driving mechanism 23 are housed in a case body 20 having a cylinder shape with a bottom. The case body 20 is hermetically fixed to a lower surface of the bottom portion 14 via a flanged pipe portion 20a, which isolates an inner environment of the case body 20 from an outer environment.

As shown in FIGS. 2 and 3, plural (five in the illustrated example) wafer receiving portions 24 having a circular concave shape, each of which receives a wafer W, are formed in a upper surface of the susceptor 2, although only one wafer W is illustrated in FIG. 3. The wafer receiving portions 24 are arranged at equal angular intervals of about 72°.

Referring to FIG. 3, each wafer receiving portion 24 has three concave portions 24a at a circumferential edge. Each of these concave portions 24a has a dimension that allows a claw 10a (described later) of the wafer arm 10 to support the wafer W from the lower surface of the wafer W. The concave portions 24a may be arranged at equal angular intervals of, for example, 120° in each wafer receiving portion 24, but are not limited to this angle. For example, the concave portions 24a may be located so that even when a gas flow in the vacuum chamber 1 is disturbed by the concave portions 24a the film deposition is not seriously affected by the disturbed gas flow pattern. In other words, the concave portions 24a are preferably located so that gas flowing over the concave portions 24a and across the wafer W takes a minimum distance until the gas flows out from the wafer W. With this, even when the gas flow is disturbed by the concave portions 24a, the effect is reduced to the minimum. For example, when the susceptor 2 is rotated in the rotation direction indicated by the arrow RD in FIG. 3, two concave portions 24a are preferably formed downstream relative to the rotation direction RD with respect to the wafer receiving portion 24. In addition, a gas flow direction with respect to the wafer W may be determined in the vacuum chamber 1 taking into consideration the rotation direction of the susceptor 2 and the gas flow pattern in the vacuum chamber 2, and thus the positions of the concave portions 24a may be determined in accordance with the determination.

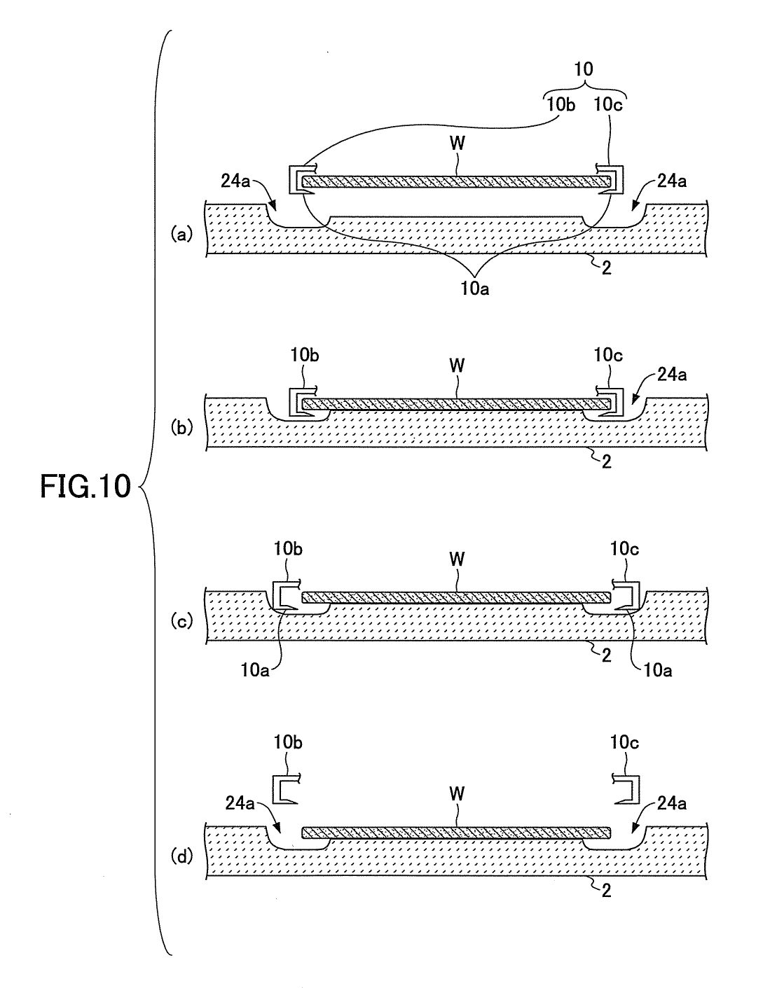

In addition, each of the concave portions 24a has an ellipsoid top view shape in this embodiment, but may have a circular or rectangular top view shape in other embodiments. Moreover, the concave portion 24a may have a rectangular cross-sectional shape, but preferably has a cross-sectional shape capable of reducing an effect of disturbing the gas flowing over the susceptor 2. For example, an inner side surface of the concave portion 24a may be inclined at a predetermined angle with respect to the vertical direction. In this embodiment, as most appropriately illustrated in FIG. 10, the inner side wall of the concave portion 24a is gently inclined from the upper surface of the susceptor 2 toward the bottom of the concave portion 24a. “Gently inclined” may include cases where the inner side wall is inclined along, for example, quadric, exponential, or parabolic lines.

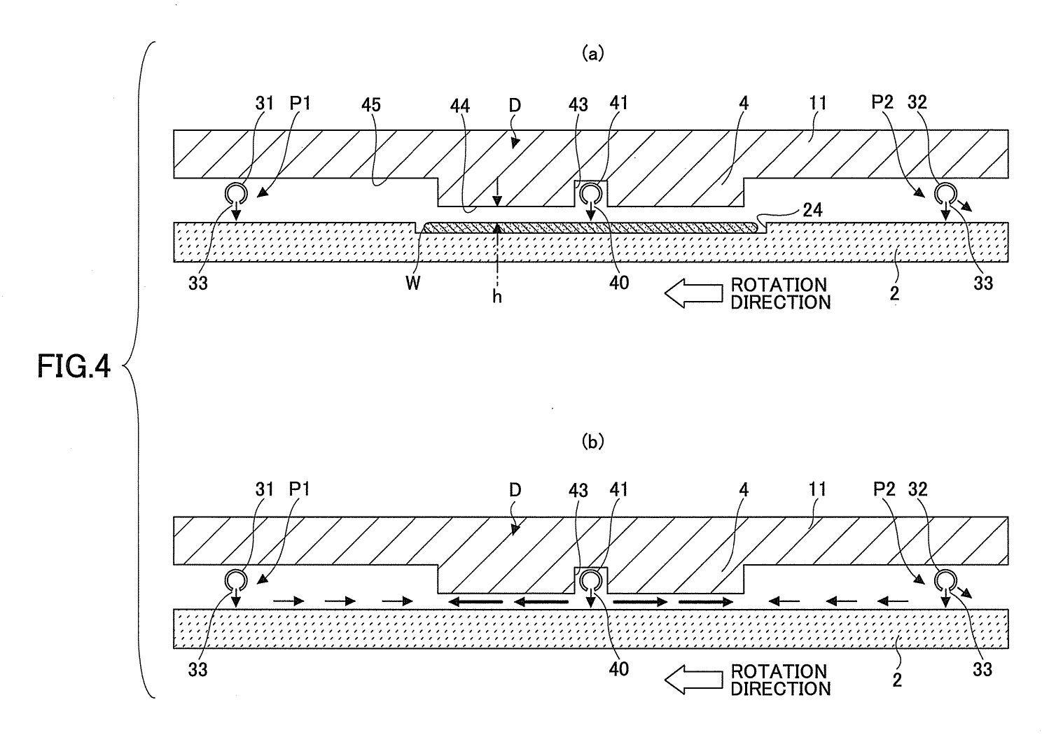

Referring to a subsection (a) of FIG. 4, the wafer receiving portion 24 and the wafer W placed in the wafer receiving portion 24 are illustrated. As shown in this drawing, the wafer receiving portion 24 has a diameter slightly larger, for example, by 4 mm than the diameter of the wafer W and a depth equal to a thickness of the wafer W. Therefore, when the wafer W is placed in the wafer receiving portion 24, a surface of the wafer W is at the same elevation of a surface of an area of the susceptor 2, the area excluding the wafer receiving portions 24. If there is a relatively large step between the area and the wafer W, gas flow turbulence is caused by the step, which may affect thickness uniformity across the wafer W. This is why the two surfaces are at the same elevation. While “the same elevation” may mean here that a height difference is less than or equal to about 5 mm, the difference has to be as close to zero as possible to the extent allowed by machining accuracy.

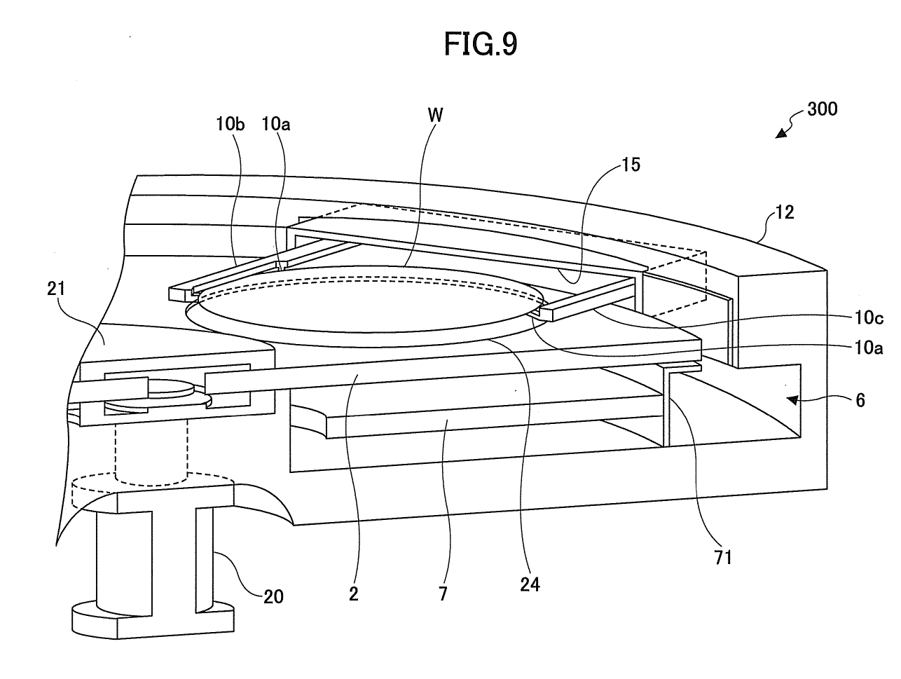

A transfer opening 15 is formed in a side wall of the chamber body 12 as shown in FIGS. 2, 3 and 9. Through the transfer opening 15, the wafer W is transferred into or out from the vacuum chamber 1 by a transfer arm 10 (FIG. 9). The transfer opening 15 is provided with a gate valve (not shown) by which the transfer opening 15 is opened or closed.

The transfer arm 10 has two arm portions 10b, 10c that are substantially horizontally arranged substantially in parallel with each other, as shown in FIG. 3. The arm portion 10b is provided with two claws 10a that depend in an L shape from the arm portion 10b, and the arm portion 10c is provided with one claw 10a that depends in an L shape from the arm portion 10c. These three claws 10a support the wafer W from a circumferential lower surface of the wafer W, which makes it possible to transfer the wafer W.

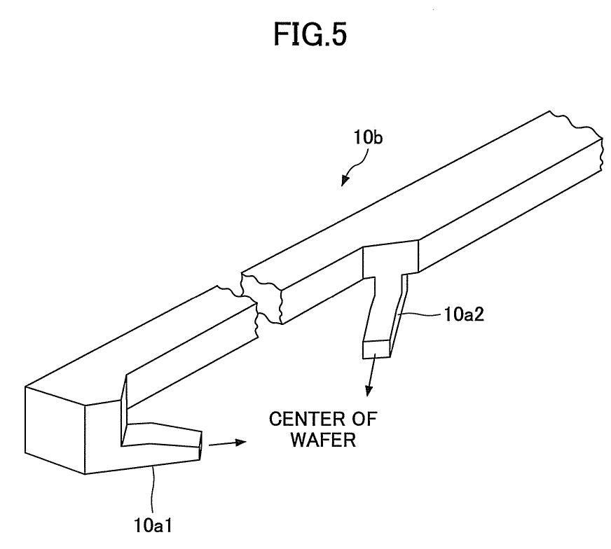

The arm portion 10b is further explained with reference to FIG. 5. As shown, the arm portion 10b has the claw 10a at the distal end of the arm portion 10b, which is referred to as a claw 10a1 hereinafter for the sake of convenience. The claw 10a1 is arranged at a predetermined angle with respect to a longitudinal direction of the arm portion 10b. Specifically, the claw 10a1 extends in a direction toward a center of the wafer W when the transfer arm 10 holds the wafer W, namely when the claw 10a1 contacts the lower surface of the wafer W. On the other hand, the other claw 10a of the arm portion 10b, which is referred to as a claw 10a2, is located substantially in a middle of the arm portion 10b. The claw 10a2 is also arranged at a predetermined angle with respect to the longitudinal direction of the arm portion 10b. Specifically, the claw 10a2 extends in a direction toward a center of the wafer W when the claw 10a2 contacts the lower surface of the wafer W.

Incidentally, the claw 10a of the other arm portion 10c is arranged at a predetermined angle with respect to a longitudinal direction of the arm portion 10c such that the claw 10a extends in a direction toward the center of the wafer W when the claw 10a contacts the lower surface of the wafer W. Because the claws 10a1, 10a2, 10a are directed toward the center of the wafer W when they contact the lower surface of the wafer W as stated above, the wafer W can be stably supported. In addition, the claws 10a1, 10a2, 10a become thinner toward the distal end, and thus can slip below the wafer W, thereby easily accessing the lower surface of the wafer W.

The claws 10a1, 10a2, 10a are preferably as small as possible because the concave portions 24a that allow the claws 10a1, 10a2, 10a to move thereto are preferably as small as possible, as long as they can stably support the wafer W. For example, the claws 10a1, 10a2, 10a may have a length (in a direction toward the center of the wafer W) of about 3 mm through about 5 mm, a width, in a direction intersecting the direction toward the center of the wafer W, of about 2 mm through about 3 mm, and a thickness of about 2 mm through about 3 mm. In addition, a vertical distance between the arm portion 10b (10c) and an upper surface of the claws 10a1, 10a2 (10a) has to be determined so that the arm portion 10b (10c) does not touch the wafer W when the wafer W is placed in the wafer receiving portion 24. This distance is preferably about 1 mm through about 1.5 mm, for example.

The transfer arm 10 can be moved into and out from the vacuum chamber 1 through the transfer opening 15, and be moved upward and downward by a driving mechanism (not shown). In addition, the two arm portions 10b, 10c may be moved closer to and away from each other by another driving mechanism (not shown). Operations of the arm portions 10b, 10c are further explained later, along with the relationship of the claws 10a1, 10a2, 10a with respect to the concave portions 24a.

Referring again to FIGS. 2 and 3, a first reaction gas nozzle 31, a second reaction gas nozzle 32, and separation gas nozzles 41, 42 are provided above the susceptor 2. These gas nozzles 31, 32, 41, 42 extend in radial directions and at predetermined angular intervals. With this configuration, the wafer receiving portion 24 can move through and below the gas nozzles 31, 32, 41, and 42. In the illustrated example, the second reaction gas nozzle 32, the separation gas nozzle 41, the first reaction gas nozzle 31, and the separation gas nozzle 42 are arranged clockwise in this order. These gas nozzles 31, 32, 41, and 42 penetrate the circumferential wall portion of the chamber body 12 and are supported by attaching their base ends, which are gas inlet ports 31a, 32a, 41a, 42a, respectively, on the outer circumference of the wall portion. Although the gas nozzles 31, 32, 41, 42 are introduced into the vacuum chamber 1 from the circumferential wall portion of the vacuum chamber 1 in the illustrated example, these gas nozzles 31, 32, 41, 42 may be introduced from a ring-shaped protrusion portion 5 (described later). In this case, an L-shaped conduit may be provided in order to be open on the outer circumferential surface of the protrusion portion 5 and on the outer upper surface of the ceiling plate 11. With such an L-shaped conduit, the gas nozzle 31 (32, 41, 42) can be connected to one opening of the L-shaped conduit inside the vacuum chamber 1 and the gas inlet port 31a (32a, 41a, 42a) can be connected to the other opening of the L-shaped conduit outside the vacuum chamber 1.

Although not shown, the reaction gas nozzle 31 is connected to a gas supplying source of bis (tertiary-butylamino) silane (BTBAS), which is a first source gas, and the reaction gas nozzle 32 is connected to a gas supplying source of O₃ (ozone) gas, which is a second source gas.

The reaction gas nozzles 31, 32 have plural ejection holes 33 to eject the corresponding source gases downward. The plural ejection holes 33 are arranged in longitudinal directions of the reaction gas nozzles 31, 32 at predetermined intervals. The ejection holes 33 have an inner diameter of about 0.5 mm, and are arranged at intervals of about 10 mm in this embodiment. The reaction gas nozzles 31, 32 are a first reaction gas supplying portion and a second reaction gas supplying portion, respectively, in this embodiment. In addition, an area below the reaction gas nozzle 31 is a first process area P1 in which the BTBAS gas is adsorbed on the wafer W, and an area below the reaction gas nozzle 32 is a second process area P2 in which the O₃ gas is adsorbed on the wafer W.

On the other hand, the separation gas nozzles 41, 42 are connected to gas supplying sources of N₂ (nitrogen) gas (not shown). The separation gas nozzles 41, 42 have plural ejection holes 40 to eject the separation gases downward from the plural ejection holes 40. The plural ejection holes 40 are arranged at predetermined intervals in longitudinal directions of the separation gas nozzles 41, 42. The ejection holes 40 have an inner diameter of about 0.5 mm, and are arranged at intervals of about 10 mm in this embodiment.

The separation gas nozzles 41, 42 are provided in separation areas D that are configured to separate the first process area P1 and the second process area 22. In each of the separation areas B, there is provided a convex portion 4 on the ceiling plate 11, as shown in FIGS. 2 through 4. The convex portion 4 has a top view shape of a sector whose apex lies at the center of the vacuum chamber 1 and whose arced periphery lies near and along the inner circumferential wall of the chamber body 12. In addition, the convex portion 4 has a groove portion 43 that extends in the radial direction as if the groove portion 43 has substantially bisected the convex portion 4. The separation gas nozzle 41 (42) is housed in the groove portion 43. A circumferential distance between the center axis of the separation gas nozzle 41 (42) and one side of the sector-shaped convex portion 4 is substantially equal to the other circumferential distance between the center axis of the separation gas nozzle 41 (42) and the other side of the sector-shaped convex portion 4. Incidentally, while the groove portion 43 is formed in order to bisect the convex portion 4 in this embodiment, the groove portion 42 is formed so that an upstream side of the convex portion 4 relative to the rotation direction of the susceptor 2 is wider, in other embodiments.

With the above configuration, there are flat low ceiling surfaces 44 (first ceiling surfaces) on both sides of the separation gas nozzle 41 (42), and high ceiling surfaces 45 (second ceiling surfaces) outside of the corresponding low ceiling surfaces 44, as shown in a subsection (a) of FIG. 4. The convex portion 4 (ceiling surface 44) provides a separation space, which is a thin space, between the convex portion 4 and the susceptor 2 in order to impede the first and the second reaction gases from entering the thin space and from being intermixed.

Referring to a subsection (b) of FIG. 4, the O₃ gas is impeded from entering the space between the convex portion 4 and the susceptor 2, the O₃ gas flowing toward the convex portion 4 from the reaction gas nozzle 32 along the rotation direction of the susceptor 2, and the BTBAS gas is impeded from entering the space between the convex portion 4 and the susceptor 2, the BTBAS gas flowing toward the convex portion 4 from the reaction gas nozzle 31 along the counter-rotation direction of the susceptor 2. “The gases being impeded from entering” means that the N₂ gas as the separation gas ejected from the separation gas nozzle 41 spreads between the first ceiling surfaces 44 and the upper surface of the susceptor 2 and flows out to a space below the second ceiling surfaces 45, which are adjacent to the corresponding first ceiling surfaces 44 in the illustrated example, so that the reaction gases cannot enter the separation space from the space below the second ceiling surfaces 45. “The reaction gases cannot enter the separation space” means not only that the gases are completely prevented from entering the separation space, but that the reaction gases cannot proceed farther toward the separation gas nozzle 41 and thus be intermixed with each other even when a fraction of the reaction gases enter the separation space. Namely, as long as such effect is demonstrated, the separation area D is to separate the first process area P1 and the second process area P2. Incidentally, the BTBAS gas or the O₃ gas adsorbed on the wafer W can pass through below the convex portion 4. Therefore, the reaction gases in “the gases being impeded from entering” mean the reaction gases in a gaseous phase.

Referring to FIGS. 1, 2, and 3, a ring-shaped protrusion portion 5 is provided on a lower surface of the ceiling plate 11 so that the inner circumference of the protrusion portion 5 faces the outer circumference of the core portion 21. The protrusion portion 5 opposes the susceptor 2 at an outer area of the core portion 21. In addition, a lower surface of the protrusion portion 5 and a lower surface of the convex portion 4 form one plane surface. In other words, a height of the lower surface of the protrusion portion 5 from the susceptor 2 is the same as a height of the lower surface of the convex portion 4, which will be referred to as a height h below. Incidentally, the convex portion 4 is formed not integrally with but separately from the protrusion portion 5 in other embodiments. FIGS. 2 and 3 show the inner configuration of the vacuum chamber 1 whose top plate 11 is removed while the convex portions 4 remain inside the vacuum chamber 1.

The separation area D is configured by forming the groove portion 43 in a sector-shaped plate to be the convex portion 4, and locating the separation gas nozzle 41 (42) in the groove portion 43 in this embodiment. However, two sector-shaped plates may be attached on the lower surface of the ceiling plate 11 by screws so that the two sector-shaped plates are located one on each side of the separation gas nozzle 41 (32).

In this embodiment, when the wafer W having a diameter of about 300 mm is supposed to be processed in the vacuum chamber 1, the convex portion 4 has a circumferential length of, for example, about 146 mm along an inner arc 1i (FIG. 3) that is at a distance 140 mm from the rotation center of the susceptor 2, and a circumferential length of, for example, about 502 mm along an outer arc 1o (FIG. 3) corresponding to the outermost portion of the wafer receiving portions 24 of the susceptor 2. In addition, a circumferential length from one side wall of the convex portion 4 through the nearest side wall of the groove portion 43 along the outer arc 1o is about 246 mm.

In addition, the height h (the subsection (a) of FIG. 4) of the lower surface of the convex portion 4, or the ceiling surface 44, measured from the upper surface of the susceptor 2 (or the wafer W) is, for example, about 0.5 mm through about 10 mm, and preferably about 4 mm. In this case, the rotational speed of the susceptor 2 is, for example, 1 through 500 revolutions per minute (rpm). In order to ascertain the separation function performed by the separation area D, the size of the convex portion 4 and the height h of the ceiling surface 44 from the susceptor 2 may be determined depending on the pressure in the vacuum chamber 1 and the rotational speed of the susceptor 2 through experimentation. Incidentally, the separation gas is N₂ in this embodiment but may be an inert gas such as He and Ar, or H₂ in other embodiments, as long as the separation gas does not affect the deposition of a silicon oxide film.

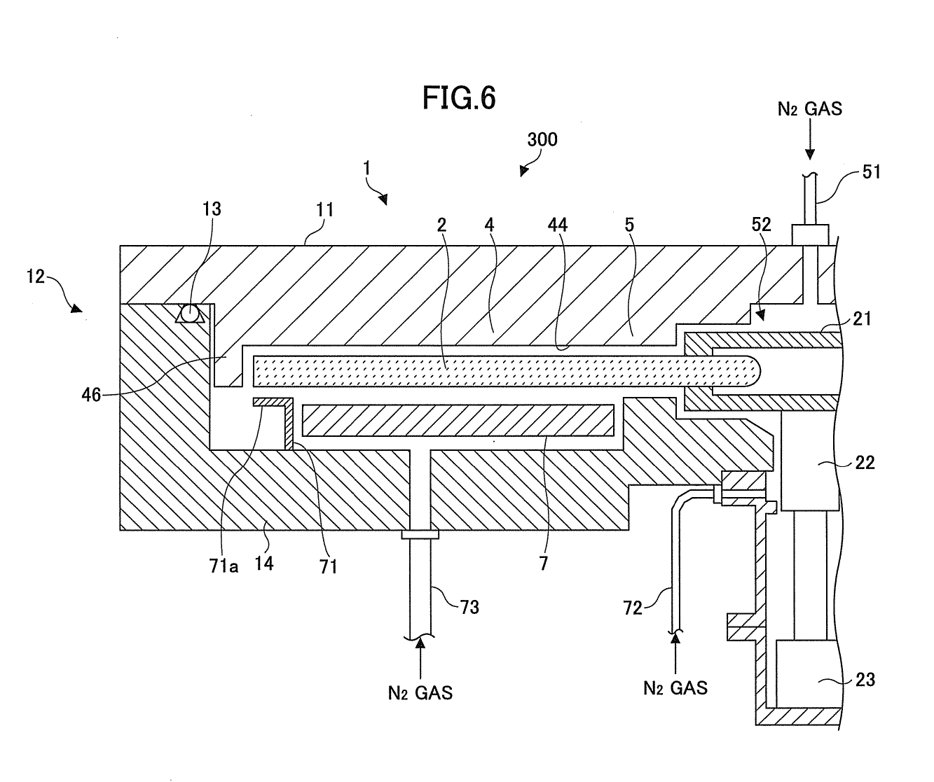

FIG. 6 shows a half portion of a cross-sectional view of the vacuum chamber 1, taken along an A-A line in FIG. 3, where the convex portion 4 is shown along with the protrusion portion 5 formed integrally with the convex portion 4. Referring to FIG. 6, the convex portion 4 has a bent portion 46 that bends in an L-shape at the outer circumferential edge of the convex portion 4. Although there are slight gaps between the bent portion 46 and the susceptor 2 and between the bent portion 46 and the chamber body 12 because the convex portion 4 is attached on the lower surface of the ceiling portion 11 and removed from the chamber body 12 along with the ceiling portion 11, the bent portion 46 substantially fills out a space between the susceptor 2 and the chamber body 12, thereby preventing the first reaction gas (BTBAS) ejected from the first reaction gas nozzle 31 and the second reaction gas (ozone) ejected from the second reaction gas nozzle 32 from being intermixed through the space between the susceptor 2 and the chamber body 12. The gaps between the bent portion 46 and the susceptor 2 and between the bent portion 46 and the chamber body 12 may be the same as the height h of the ceiling surface 44 from the susceptor 2. In the illustrated example, a side wall facing the outer circumferential surface of the susceptor 2 serves as an inner circumferential wall of the separation area D.

Now, referring again to FIG. 1, which is a cross-sectional view taken along a B-B line in FIG. 3, the chamber body 12 has an indented portion at the inner circumferential portion opposed to the outer circumferential surface of the susceptor 2. The indented portion is referred to as an evacuation area 6 hereinafter. Below the evacuation area 6, there is an evacuation port 61 (see FIG. 3 for another evacuation port 62) which is connected to a vacuum pump 64 via an evacuation pipe 63, which can also be used for the evacuation port 62. In addition, the evacuation pipe 63 is provided with a pressure controller 65. Plural pressure controllers 65 may be provided to the corresponding evacuation ports 61, 62.

Referring again to FIG. 3, the evacuation port 61 is located between the first reaction gas nozzle 31 and the convex portion 4 that is located downstream relative to the clockwise rotation direction of the susceptor 2 in relation to the first reaction gas nozzle 31, when viewed from above. With this configuration, the evacuation port 61 can substantially exclusively evacuate the BTBAS gas ejected from the reaction gas nozzle 31. On the other hand, the evacuation port 62 is located between the second reaction gas nozzle 32 and the convex portion 4 that is located downstream relative to the clockwise rotation direction of the susceptor 2 in relation to the second reaction gas nozzle 32, when viewed from above. With this configuration, the evacuation port 62 can substantially exclusively evacuate the O₃ gas ejected from the reaction gas nozzle 32. Therefore, the evacuation ports 61, 62 so configured may assist the separation areas D to prevent the BTBAS gas and the O₃ gas from being intermixed.

Although the two evacuation ports 61, 62 are made in the chamber body 12 in this embodiment, three evacuation ports may be provided in other embodiments. For example, an additional evacuation port may be made in an area between the second reaction gas nozzle 32 and the separation area located upstream relative to the clockwise rotation of the susceptor 2 in relation to the second reaction gas nozzle 32. In addition, another additional evacuation port may be made at a predetermined position in the chamber body 12. While the evacuation ports 61, 62 are located below the susceptor 2 to evacuate the vacuum chamber 1 through an area between the inner circumferential wall of the chamber body 12 and the outer circumferential surface of the susceptor 2 in the illustrated example, the evacuation ports may be located in the side wall of the chamber body 12. In addition, when the evacuation ports 61, 62 are provided in the side wall of the chamber body 12, the evacuation ports 61, 62 may be located higher than the susceptor 2. In this case, the gases flow along the upper surface of the susceptor 2 into the evacuation ports 61, 62 located higher the susceptor 2. Therefore, it is advantageous in that particles in the vacuum chamber 1 are not blown upward by the gases, compared to when the evacuation ports are provided, for example, in the ceiling plate 11.

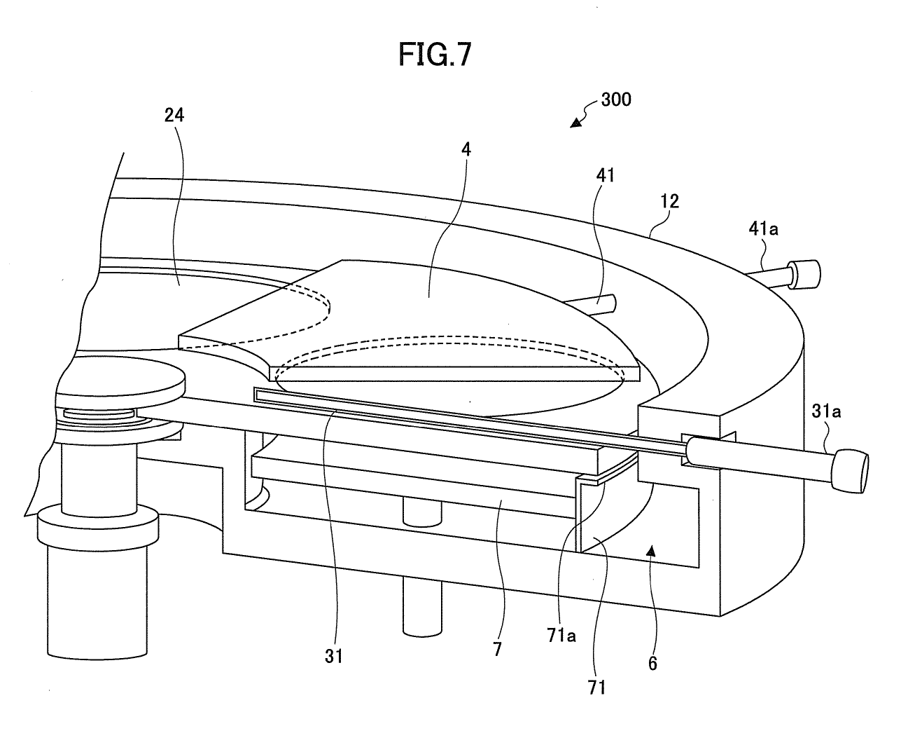

As shown in FIGS. 1, 6, and 7, a ring-shaped heater unit 7 as a heating portion is provided in a space between the bottom portion 14 of the chamber body 12 and the susceptor 2, so that the wafers W placed on the susceptor 2 are heated through the susceptor 2 at a temperature determined by a process recipe. In addition, a cover member 71 is provided beneath the susceptor 2 and near the outer circumference of the susceptor 2 in order to surround the heater unit 7, so that the space where the heater unit 7 is located is partitioned from the outside area of the cover member 71. The cover member 71 has a flange portion 71a at the top. The flange portion 71a is arranged so that a slight gap is maintained between the lower surface of the susceptor 2 and the flange portion in order to prevent gas from flowing inside the cover member 71.

Referring back to FIG. 1, the bottom portion 14 of the chamber body 12 has a raised portion in an inside area of the ring-shaped heater unit 7. The upper surface of the raised portion comes close to the back surface of the susceptor 2 and the core portion 21, leaving slight gaps between the raised portion and the susceptor 2 and between the raised portion and the core portion 21. In addition, the bottom portion 14 has a center hole through which the rotational shaft 22 passes. The inner diameter of the center hole is slightly larger than the diameter of the rotational shaft 22, leaving a gap for pressure communication with the case body 20 through the flanged pipe portion 20a. A purge gas supplying pipe 72 is connected to an upper portion of the flanged pipe portion 20a. In addition, plural purge gas supplying pipes 73 are connected at predetermined angular intervals to areas below the heater unit 7 in order to purge the space where the heater unit 7 is housed.

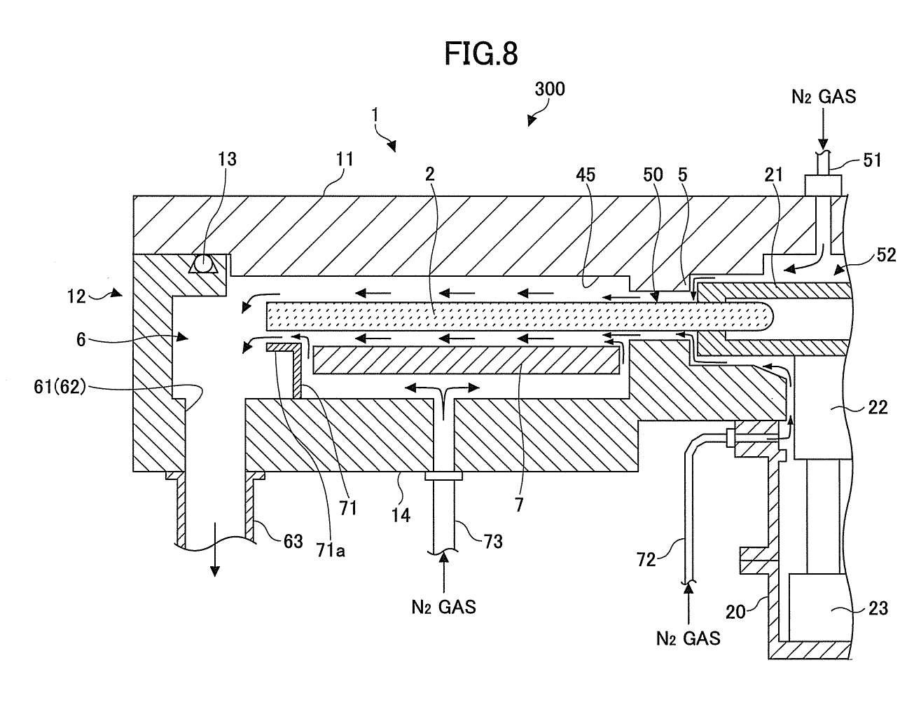

With these configurations, N₂ purge gas may flow from the purge gas supplying pipe 72 to the heater unit space through the gap between the rotational shaft 22 and the center hole of the bottom portion 14, the gap between the core portion 21 and the raised portion of the bottom portion 14, and the gap between the raised portion of the bottom portion 14 and the lower surface of the susceptor 2. In addition, N₂ purge gas may flow from the purge gas supplying pipes 73 to the space below the heater unit 7. Then, these N₂ purge gases flow into the evacuation port 61 through the gap between the flange portion 71a of the cover member 71 and the lower surface of the susceptor 2. These flows of the N₂ purge gases are schematically illustrated by arrows in FIG. 8. These N₂ purge gases serve as separation gases that prevent the first (second) reaction gas from flowing around the space below the susceptor 2 to be intermixed with the second (first) reaction gas.

Referring to FIG. 8, a separation gas supplying pipe 51 is connected to the top center portion of the ceiling plate 11 of the vacuum chamber 1, so that N₂ gas is supplied as a separation gas to a space 52 between the ceiling plate 11 and the core portion 21. The separation gas supplied to the space 52 flows through the thin gap 50 between the protrusion portion 5 and the susceptor 2 and then along the upper surface of the susceptor 2, and reaches the evacuation area 6. Because the space 52 and the gap 50 are filled with the N₂ gas, the reaction gases (BTBAS, O₃) cannot be intermixed through the center portion of the susceptor 2. In other words, the film deposition apparatus according to this embodiment is provided with a center area C that is defined by the center portion of the susceptor 2 and the vacuum chamber 1 in order to isolate the first process area P1 and the second process area P2 and is configured to have an ejection opening that ejects the separation gas toward the upper surface of the susceptor 2. The ejection opening corresponds to the gap 50 between the protrusion portion 5 and the susceptor 2, in the illustrated example.

In addition, the film deposition apparatus 300 according to this embodiment is provided with a control portion 100 that controls total operations of the deposition apparatus 300. The control portion 100 includes a process controller 100a formed of, for example, a computer, a user interface portion 100b, and a memory device 100c. The user interface portion 100b has a display that shows operations of the film deposition apparatus, and a key board or a touch panel (not shown) that allows an operator of the film deposition apparatus 300 to select process recipes and an administrator of the film deposition apparatus to change parameters in the process recipes.

The memory device 100c stores a control program and a process recipe that cause the controlling portion 100 to carry out various operations of the deposition apparatus, and according to various parameters in the process recipe. These programs have groups of steps for carrying out the operations described later, for example. These programs are installed into and run by the process controller 100a by instructions from the user interface portion 100b. In addition, the programs are stored in a computer readable storage medium 100d and installed into the memory device 100c from the storage medium 100d through an input/output (I/O) device (not shown) corresponding to the computer readable storage medium 100d. The computer readable storage medium 100d may be a hard disk, a compact disc, a magneto optical disk, a memory card, a floppy disk, or the like. Moreover, the programs may be downloaded to the memory device 100c through a communications network.

Next, operations of the film deposition apparatus, or a film deposition method using the film deposition apparatus 300 according to this embodiment of the present invention are described.

(Wafer Transfer-In Process)

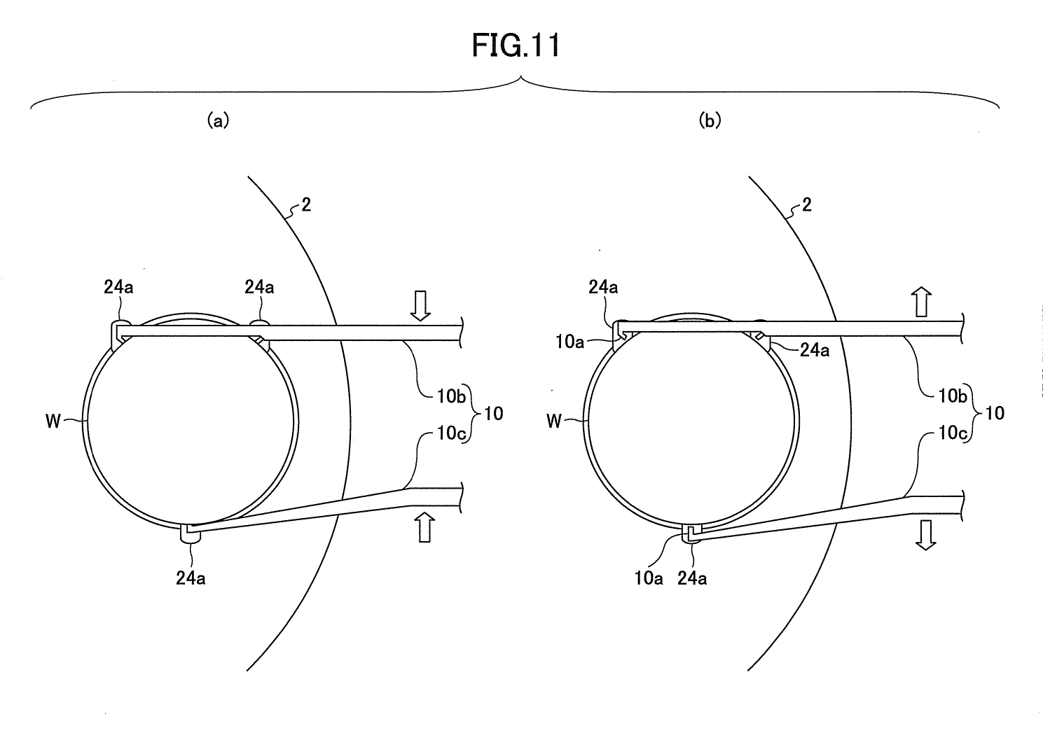

First, a process where the wafer W is placed on the susceptor is explained with reference to FIGS. 10 and 11. The susceptor 2 is rotated so that one of the wafer receiving portions 24 is in alignment with the transfer opening 15, and the gate valve (not shown) is opened. Next, the wafer W is supported from the lower surface thereof by the three claws 10a (only two claws 10a are shown in subsections (a) through (d) of FIG. 10) of the transfer arm 10, brought into the vacuum chamber 1 through the transfer opening 15 by the transfer arm 10, and held above the wafer receiving portion 24 of the susceptor 2 (see FIG. 9). At this time, the arm portions 10b, 10c of the transfer arm 10 come close to each other as shown in the subsection (a) of FIG. 11, which allows the claws 10a to contact the lower surface of the wafer W, and thereby to support the wafer W. Next, as shown in the subsection (b) of FIG. 10, the transfer arm 10 moves downward. When the claws 10a enter the concave portions 24a of the wafer receiving portion 24 and thus are positioned lower than the upper surface of the wafer receiving portion 24, the lower surface of the wafer W contacts the upper surface of the wafer receiving portion 24 and the claws 10a are away from the lower surface of the wafer W. Subsequently, as shown in the subsection (b) of FIG. 11, the arm portions 10b, 10c of the transfer arm 10 move away from each other. With this, the claws 10a are positioned outside an edge of the wafer W (the subsection (c) of FIG. 10). Then, the transfer arm 10 moves upward (the subsection (d) of FIG. 10), is pulled away from the vacuum chamber 1, and thus transferring one of the wafers W to the one of the wafer receiving portions 24 is completed.

### (Film Deposition Process)

After the series of operations above are repeated five times and thus five wafers W are loaded on the susceptor 2, the vacuum chamber 1 is evacuated by the vacuum pump 64 (FIG. 1) to a predetermined pressure. Next, the susceptor 2 starts rotating clockwise when seen from above. The susceptor 2 is heated to a predetermined temperature (e.g., 300° C.) in advance by the heater unit 7, which in turn heats the wafers W placed on the susceptor 2. After the wafers W are heated and maintained at the predetermined temperature, which may be confirmed by a temperature sensor (not shown), the first reaction gas (BTBAS) is supplied to the first process area P1 through the first reaction gas nozzle 31, and the second reaction gas (O₃) is supplied to the second process area P2 through the second reaction gas nozzle 32. In addition, the separation gases (N₂) are supplied to the separation areas D through the separation nozzles 41, 42.

When the wafer W passes through the first process area P1 below the first reaction gas nozzle 31, BTBAS molecules are adsorbed on the surface of the wafer W, and when the wafer W passes through the second process area P2 below the second reaction gas nozzle 32, O₃ molecules are adsorbed on the surface of the wafer W, so that the BTBAS molecules are oxidized by the O₃ molecules. Therefore, when the wafer W passes through both areas P1, P2 with one rotation of the susceptor 2, one molecular layer of silicon dioxide is formed on the surface of the wafer W. Then, the wafer W alternately passes through areas P1, P2 plural times, and a silicon dioxide layer having a predetermined thickness is formed on the surfaces of the wafers W. After the silicon dioxide film having the predetermined thickness is deposited, the supply of the BTBAS gas and the supply of the O₃ gas are stopped, and the rotation of the susceptor 2 is stopped.

### (Wafer Transfer-Out Process)

After the film deposition is completed, the vacuum chamber 1 is purged. Next, the wafers W are sequentially transferred out from the vacuum chamber 1 by the transfer arm 10 in a manner opposite to the transfer-in process explained with reference to FIGS. 10 and 11. Namely, after the wafer receiving portion 24 is aligned to the transfer opening 15 and the gate valve is opened, the transfer arm 10 enters the vacuum chamber 1 and rests above the wafer W. At this time, the arm portions 10b, 10c of the transfer arm 10 move away from each other. In other words, the claws 10a of the transfer arm 10 are outside the edge of the wafer W. Next, the transfer arm 10 moves downward so that the claws 10a enter the concave portions 24a, and the arm portions 10b, 10c move closer to each other. Then, the transfer arm 10 moves upward; the lower surface of the wafer W is supported by the claws 10a; and thus the wafer W is moved upward. After this, the transfer arm 10 moves out from the vacuum chamber 1, and transfers the wafer W out to another transfer arm (not shown). Subsequently, the series of the above procedures is repeated until all the wafers W are transferred out.

As stated above, in the film deposition apparatus 300 according to this embodiment of the present invention, because the wafer receiving portion 24 of the susceptor 2 is provided along the circumferential edge thereof with the concave portions 24a that allow the claws 10a of the transfer arm 10 to enter, when the claws 10a supporting the wafer W from the lower surface of the wafer W enter the concave portions 24a, the wafer W can be placed on the wafer receiving portion 24. In addition, when the claws 10a enter the concave portions 24a and the transfer arm 10 moves upward, the claws 10a can support the wafer W from the lower surface of the wafer W and thus the transfer arm 10 can transfer out the wafer W. Therefore, the film deposition apparatus 300 according to this embodiment can eliminate the need for the lift pins that move the wafer upward/downward and the need for the through holes through which the lift pins move upward/downward. Accordingly, problems of wafer slippage in the wafer receiving portion and degradation of the temperature uniformity across the wafer, which may originate from the through holes made in the susceptor, are not caused in the film deposition apparatus 300 according to this embodiment.

Incidentally, during the deposition process above, the N₂ gas as the separation gas is supplied from the separation gas supplying pipe 51, and is ejected toward the upper surface of the susceptor 2 from the center area C, that is, the gap 50 between the protrusion portion 5 and the susceptor 2. In this embodiment, a space below the second ceiling surface 45, where the reaction gas nozzle 31 (32) is arranged, has a lower pressure than the center area C and the thin space between the first ceiling surface 44 and susceptor 2. This is because the evacuation area 6 is provided adjacent to the space below the ceiling surface 45 (see FIGS. 1 and 3) and the space is directly evacuated through the evacuation area 6. Additionally, it is partly because the thin space is provided so that the height h can maintain the pressure difference between the thin space and the place where the reaction gas nozzle 31 (32) or the first (the second) process area P1 (P2) is located.

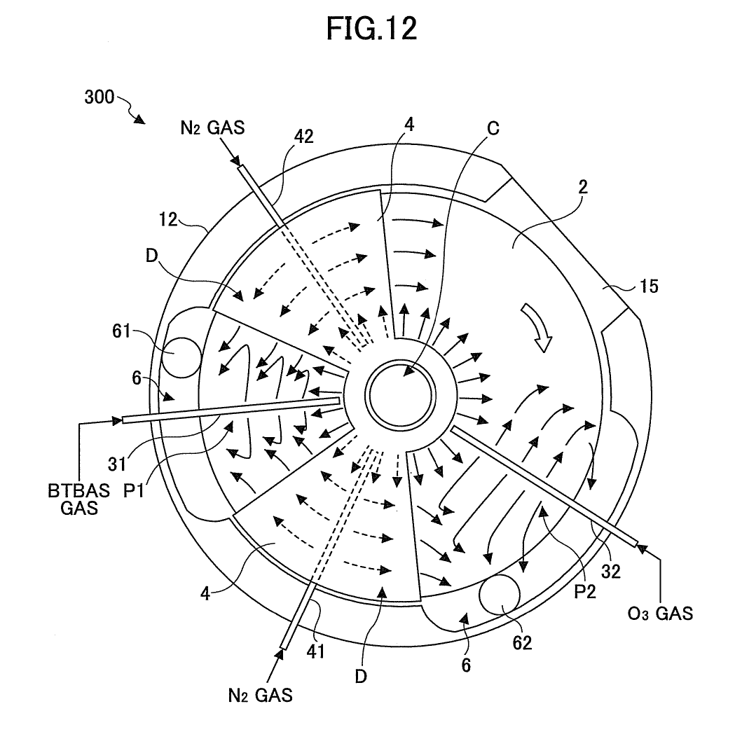

Next, the flow patterns of the gases supplied into the vacuum chamber 1 from the gas nozzles 31, 32, 41, 42 are described in reference to FIG. 12, which schematically shows the flow patterns. As shown, part of the O₃ gas ejected from the second reaction gas nozzle 32 hits and flows along the upper surface of the susceptor 2 (and the surface of the wafer W) in a direction opposite to the rotation direction of the susceptor 2. Then, the O₃ gas is pushed back by the N₂ gas flowing along the rotation direction, and changes the flow direction toward the edge of the susceptor 2 and the inner circumferential wall of the chamber body 12. Finally, this part of the O₃ gas flows into the evacuation area 6 and is evacuated from the vacuum chamber 1 through the evacuation port 62.

Another part of the O₃ gas ejected from the second reaction gas nozzle 32 hits and flows along the upper surface of the susceptor 2 (and the surface of the wafers W) in the same direction as the rotation direction of the susceptor 2. This part of the O₃ gas mainly flows toward the evacuation area 6 due to the N₂ gas flowing from the center portion C and suction force through the evacuation port 62. On the other hand, a small portion of this part of the O₃ gas flows toward the separation area D located downstream of the rotation direction of the susceptor 2 in relation to the second reaction gas nozzle 32 and may enter the gap between the ceiling surface 44 and the susceptor 2. However, because the height h of the gap is designed so that the O₃ gas is impeded from flowing into the gap at film deposition conditions intended, the small portion of the O₃ gas cannot flow into the gap. Even when a small fraction of the O₃ gas flows into the gap, the fraction of the O₃ gas cannot flow farther into the separation area D, because the fraction of the O₃ gas can be pushed backward by the N₂ gas ejected from the separation gas nozzle 41. Therefore, substantially all the part of the O₃ gas flowing along the upper surface of the susceptor 2 in the rotation direction flows into the evacuation area 6 and is evacuated by the evacuation port 62, as shown in FIG. 12.

Similarly, part of the BTBAS gas ejected from the first reaction gas nozzle 31 to flow along the upper surface of the susceptor 2 in a direction opposite to the rotation direction of the susceptor 2 is prevented from flowing into the gap between the susceptor 2 and the ceiling surface 44 of the convex portion 4 located upstream relative to the rotation direction of the susceptor 2 in relation to the first reaction gas nozzle 31. Even if only a fraction of the BTBAS gas flows into the gap, this BTBAS gas is pushed backward by the N₂ gas ejected from the separation gas nozzle 41 in the separation area D. The BTBAS gas pushed backward flows toward the outer circumferential edge of the susceptor 2 and the inner circumferential wall of the chamber body 12, along with the N₂ gases from the separation gas nozzle 41 and the center portion C, and then is evacuated by the evacuation port 61 through the evacuation area 6.

Another part of the BTBAS gas ejected from the first reaction gas nozzle 31 to flow along the upper surface of the susceptor 2 (and the surface of the wafers W) in the same direction as the rotation direction of the susceptor 2 cannot flow into the gap between the susceptor 2 and the ceiling surface 44 of the convex portion 4 located downstream relative to the rotation direction of the susceptor 2 in relation to the first reaction gas supplying nozzle 31. Even if a fraction of this part of the BTBAS gas flows into the gap, this BTBAS gas is pushed backward by the N₂ gases ejected from the center portion C and the separation gas nozzle 42 in the separation area D. The BTBAS gas pushed backward flows toward the evacuation area 6, along with the N₂ gases from the separation gas nozzle 41 and the center portion C, and then is evacuated by the evacuation port 61.

As stated above, the separation areas D may prevent the BTBAS gas and the O₃ gas from flowing thereinto, or may greatly reduce the amount of the BTBAS gas and the O₃ gas flowing thereinto, or may push the BTBAS gas and the O₃ gas backward. The BTBAS molecules and the O₃ molecules adsorbed on the wafer W are allowed to go through the separation area D, contributing to the film deposition.

Additionally, the BTBAS gas in the first process area P1 (the O₃ gas in the second process area P2) is prevented from flowing into the center area C, because the separation gas is ejected toward the outer circumferential edge of the susceptor 2 from the center area C, as shown in FIGS. 8 and 12. Even if a fraction of the BTBAS gas in the first process area P1 (the O₃ gas in the second process area P2) flows into the center area C, the BTBAS gas (the O₃ gas) is pushed backward, so that the BTBAS gas in the first process area P1 (the O₃ gas in the second process area P2) is prevented from flowing into the second process area P2 (the first process area P1) through the center area C.

Moreover, the BTBAS gas in the first process area P1 (the O₃ gas in the second process area P2) is prevented from flowing into the second process area P2 (the first process area P1) through the space between the susceptor 2 and the inner circumferential wall of the chamber body 12. This is because the bent portion 46 is formed downward from the convex portion 4 so that the gaps between the bent portion 46 and the susceptor 2 and between the bent portion 46 and the inner circumferential wall of the chamber body 12 are as small as the height h of the ceiling surface 44 of the convex portion 4, the height h being measured from the susceptor 2, thereby substantially avoiding pressure communication between the two process areas, as stated above. Therefore, the BTBAS gas is evacuated from the evacuation port 61, and the O₃ gas is evacuated from the evacuation port 62, and thus the two reaction gases are not intermixed. In addition, the space below the susceptor 2 is purged by the N₂ gas supplied from the purge gas supplying pipes 72, 73. Therefore, the BTBAS gas cannot flow through below the susceptor 2 into the second process area P2.

An example of process parameters preferable in the film deposition apparatus according to this embodiment is listed below.

rotational speed of the susceptor 2: 1-500 rpm (in the case of the wafer W having a diameter of 300 mm)

pressure in the vacuum chamber 1: 1067 Pa (8 Torr)

wafer temperature: 350° C.

flow rate of BTBAS gas: 100 sccm

flow rate of O₃ gas: 10000 sccm

flow rate of N₂ gas from the separation gas nozzles 41, 42: 20000 sccm

flow rate of N₂ gas from the separation gas supplying pipe 51: 5000 sccm

the number of rotations of the susceptor 2: 600 rotations (depending on the film thickness required)

According to the film deposition apparatus of this embodiment, because the film deposition apparatus has the separation areas D including the low ceiling surface 44 between the first process area P1, to which the BTBAS gas is supplied from the first reaction gas nozzle 31, and the second process area P2, to which the O₃ gas is supplied from the second reaction gas nozzle 32, the BTBAS gas (the O₃ gas) is prevented from flowing into the second process area P2 (the first process area P1) and being intermixed with the O₃ gas (the BTBAS gas). Therefore, MLD (or ALD) mode deposition of silicon dioxide is assuredly performed by rotating the susceptor 2 on which the wafers W are placed in order to allow the wafers W to pass through the first process area P1, the separation area D, the second process area P2, and the separation area D. In addition, the separation areas D further include the separation gas nozzles 41, 42 from which the N₂ gases are ejected in order to further assuredly prevent the BTBAS gas (the O₃ gas) from flowing into the second process area P2 (the first process area P1) and being intermixed with the O₃ gas (the BTBAS gas). Moreover, because the vacuum chamber 1 of the film deposition apparatus according to this embodiment has the center area C having the ejection holes from which the N₂ gas is ejected, the BTBAS gas (the O₃ gas) is prevented from flowing into the second process area P2 (the first process area P1) through the center area C and being intermixed with the O₃ gas (the BTBAS gas). Furthermore, because the BTBAS gas and the O₃ gas are not intermixed, almost no deposits of silicon dioxide are made on the susceptor 2, thereby reducing particle problems.

Incidentally, although the susceptor 2 has the five wafer receiving portions 24 and five wafers W placed in the corresponding wafer receiving portions 24 can be processed in one run in this embodiment, only one wafer W is placed in one of the five wafer receiving portions 24, or the susceptor 2 may have only one wafer receiving portion 24.

In addition, not being limited to MLD of a silicon oxide film, the film deposition apparatus 300 is used to carry out MLD of a silicon nitride film. As a nitriding gas in the case of MLD of silicon nitride, ammonia (NH₃), hydrazine (N₂H₂), and the like are used.

In addition, as a source gas for the silicon oxide or nitride film deposition, dichlorosilane (DCS), hexadichlorosilane (HCD, tris(dimethylamino)silane (3DMAS), tetra ethyl ortho silicate (TEOS), and the like may be used rather than BTBAS.

Moreover, the film deposition apparatus according to an embodiment of the present invention may be used for MLD of an aluminum oxide (Al₂O₃) film using trimethylaluminum (TMA) and O₃ or oxygen plasma, a zirconium oxide (ZrO₂) film using tetrakis(ethylmethylamino)zirconium (TEMAZ) and O₃ or oxygen plasma, a hafnium oxide (HfO₂) film using tetrakis(ethylmethylamino)hafnium (TEMAHf) and O₃ or oxygen plasma, a strontium oxide (SrO) film using bis(tetra methyl heptandionate)strontium (Sr (THD)₂) and O₃ or oxygen plasma, a titanium oxide (TiO) film using (methyl-pentadionate)(bis-tetra-methyl-heptandionate)titanium (Ti(MPD)(THD)) and O₃ or oxygen plasma, and the like, rather than the silicon oxide film and the silicon nitride film.

Because a larger centrifugal force is applied to the gases in the vacuum chamber 1 at a position closer to the outer circumference of the susceptor 2, the BTBAS gas, for example, flows toward the separation area D at a higher speed in the position closer to the outer circumference of the susceptor 2. Therefore, the BTBAS gas is more likely to enter the gap between the ceiling surface 44 and the susceptor 2 in the position closer to the circumference of the susceptor 2. Because of this situation, when the convex portion 4 has a greater width (a longer arc) toward the circumference, the BTBAS gas cannot flow farther into the gap in order to be intermixed with the O₃ gas. In view of this, it is preferable for the convex portion 4 to have a sector-shaped top view, as explained above.

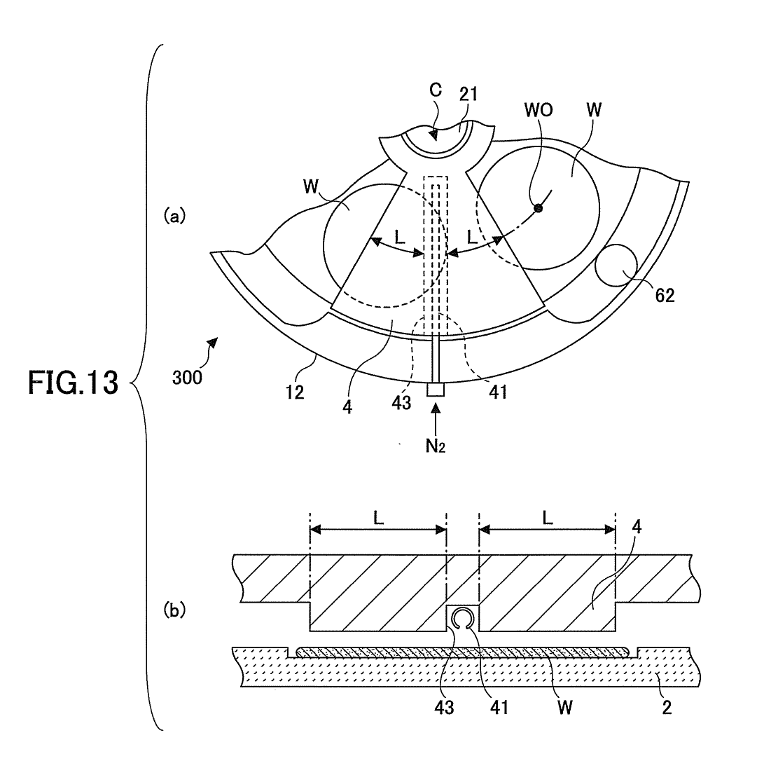

The size of the convex portion 4 (or the ceiling surface 44) is exemplified again below. Referring to subsections (a) and (b) of FIG. 13, the ceiling surface 44 that creates the thin space in both sides of the separation gas nozzle 41 (42) may preferably have a length L ranging from about one-tenth of a diameter of the wafer W through about a diameter of the wafer W, preferably, about one-sixth or more of the diameter of the wafer W along an arc that corresponds to a route through which a wafer center WO passes. Specifically, the length L is preferably about 50 mm or more when the wafer W has a diameter of 300 mm. When the length L is small, the height h of the thin space between the ceiling surface 44 and the susceptor 2 (wafer W) has to be accordingly small in order to effectively prevent the reaction gases from flowing into the thin space. However, when the length L becomes too small and thus the height h has to be extremely small, the susceptor 2 may hit the ceiling surface 44, which may cause wafer breakage and wafer contamination through particle generation. Therefore, measures to damp vibration of the susceptor 2 or measures to stably rotate the susceptor 2 are required in order to avoid the susceptor 2 hitting the ceiling surface 44. On the other hand, when the height h of the thin space is kept relatively greater while the length L is small, a rotational speed of the susceptor 2 has to be lower in order to avoid the reaction gases flowing into the thin gap between the ceiling surface 44 and the susceptor 2, which is rather disadvantageous in terms of production throughput. From these considerations, the length L of the ceiling surface 44 along the arc corresponding to the route of the wafer center WO is preferably about 50 mm or more. However, the size of the convex portion 4 or the ceiling surface 44 is not limited to the above size, but may be adjusted depending on the process parameters and the size of the wafer to be used. In addition, as clearly understood from the above explanation, the height h of the thin space may be adjusted depending on an area of the ceiling surface 44 in addition to the process parameters and the size of the wafer to be used, as long as the thin space has a height that allows the separation gas to flow from the separation area D through the process area P1 (P2).

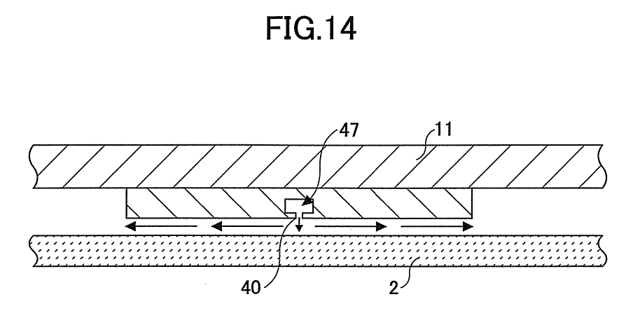

The separation gas nozzle 41 (42) is located in the groove portion 43 formed in the convex portion 4 and the lower ceiling surfaces 44 are located in both sides of the separation gas nozzle 41 (42) in the above embodiment. However, as shown in FIG. 14, a conduit 47 extending along the radial direction of the susceptor 2 may be made inside the convex portion 4, instead of the separation gas nozzle 41 (42), and plural holes 40 may be formed along the longitudinal direction of the conduit 47 so that the separation gas (N₂ gas) may be ejected from the plural holes 40 in other embodiments.

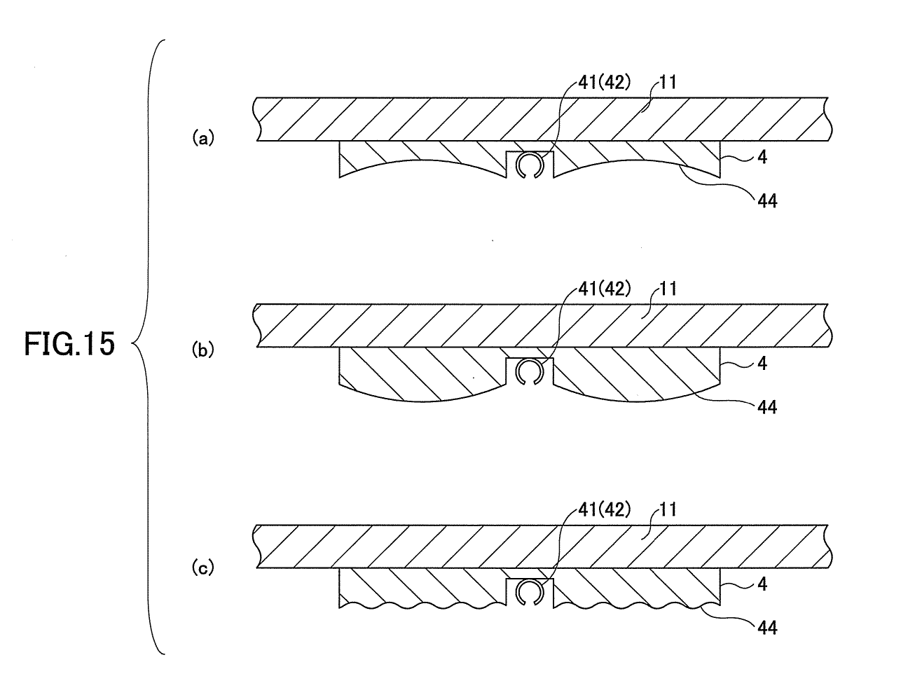

The ceiling surface 44 of the separation area D is not necessarily flat in other embodiments. For example, the ceiling surface 44 may be concavely curved as shown in a subsection (a) of FIG. 15, convexly curved as shown in a subsection (b) of FIG. 15, or corrugated as shown in a subsection (c) of FIG. 15.

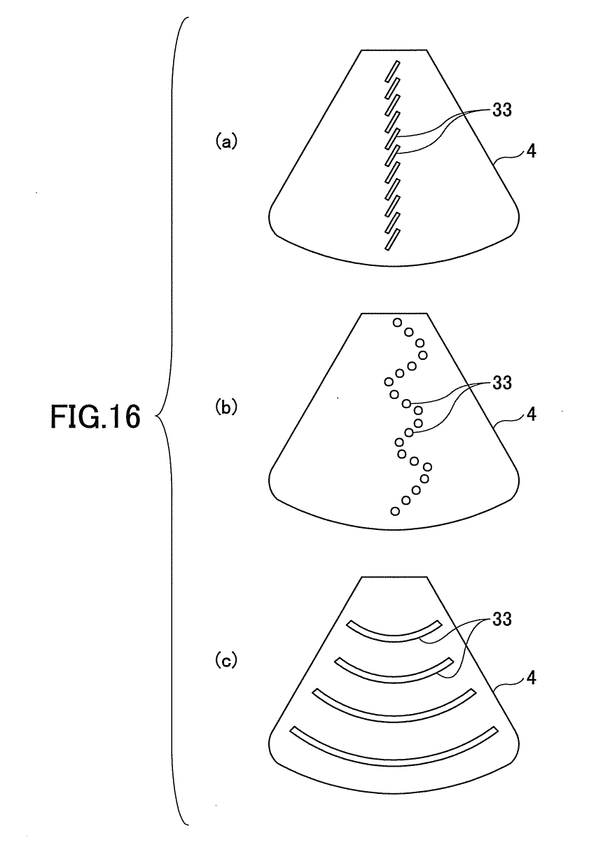

In addition, the convex portion 4 may be hollow and the separation gas may be introduced into the hollow convex portion 4. In this case, the plural gas ejection holes 33 may be arranged as shown in subsections (a) through (c) of FIG. 16.

Referring to the subsection (a) of FIG. 16, each of the plural gas ejection holes 33 has a shape of a slanted slit. These slanted slits (gas ejection holes 33) are arranged to be partially overlapped with an adjacent slit along the radial direction of the susceptor 2. In the subsection (b) of FIG. 16, the plural gas ejection holes 33 are circular. These circular holes (gas ejection holes 33) are arranged along a serpentine line that extends in the radial direction as a whole. In the subsection (c) of FIG. 16, each of the plural gas ejection holes 33 has the shape of an arc-shaped slit. These arc-shaped slits (gas ejection holes 33) are arranged at predetermined intervals in the radial direction.

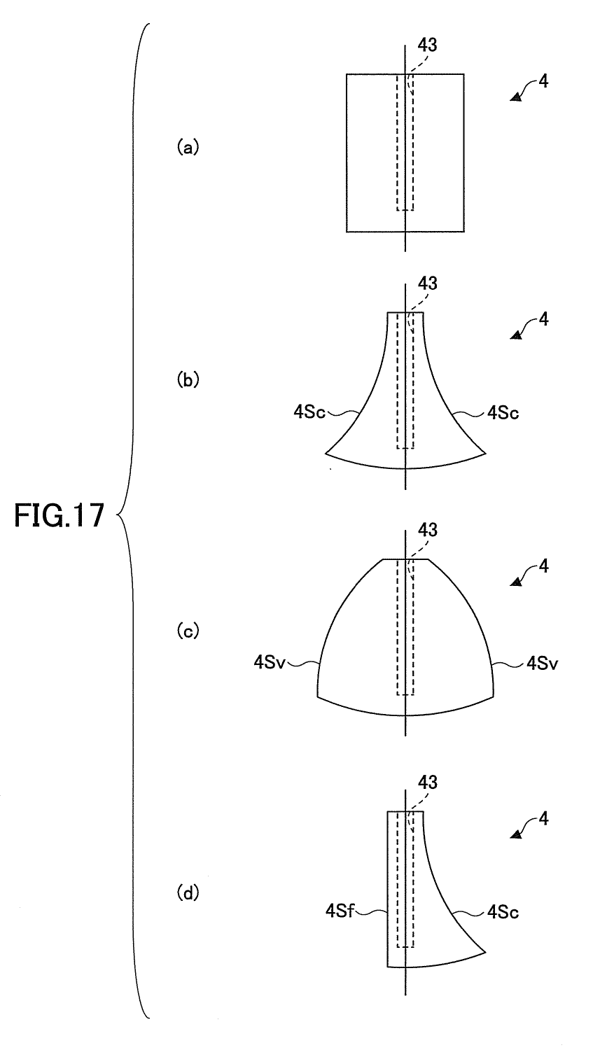

While the convex portion 4 has the sector-shaped top view shape in this embodiment, the convex portion 4 may have a rectangle top view shape as shown in a subsection (a) of FIG. 17D, or a square top view shape in other embodiments. Alternatively, the convex portion 4 may be sector-shaped as a whole in the top view and have concavely curved side surfaces 4Sc, as shown in a subsection (b) of FIG. 17. In addition, the convex portion 4 may be sector-shaped as a whole in the top view and have convexly curved side surfaces 4Sv, as shown in a subsection (c) of FIG. 17. Moreover, an upstream portion, of the convex portion 4 relative to the rotation direction of the susceptor 2 (FIG. 1) may have a concavely curved side surface 4Sc and a downstream portion of the convex portion 4 relative to the rotation direction of the susceptor 2 (FIG. 1) may have a flat side surface 4Sf, as shown in a subsection (d) of FIG. 17. Incidentally, dotted lines in the subsections (a) through (d) of FIG. 17 represent the groove portions 43. In these cases, the separation gas nozzle 41 (42), which is housed in the groove portion 43, extends from the center portion of the vacuum chamber 1, for example, from the protrusion portion 5.

The heater unit 7 for heating the wafers W is configured to have a lamp heating element instead of the resistance heating element. In addition, the heater unit 7 may be located above the susceptor 2, or above and below the susceptor 2.

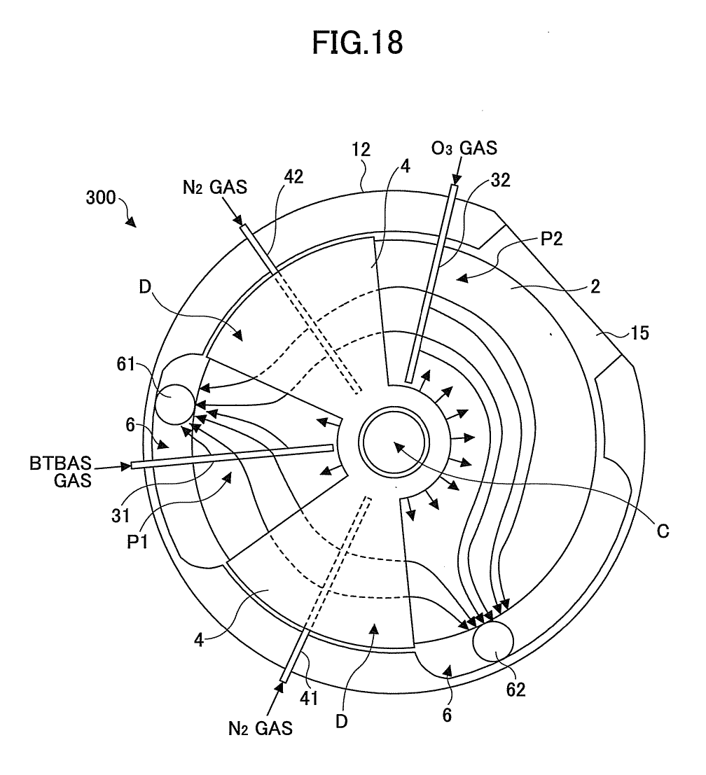

The process areas P1, P2 and the separation area D may be arranged as shown in FIG. 18, in other embodiments. Referring to FIG. 18, the second reaction gas nozzle 32 for supplying the second reaction gas (e.g., O₃ gas) is located upstream in the rotation direction relative to the transfer opening 15, or between the separation gas nozzle 42 and the transfer opening 15. Even in such an arrangement, the gases ejected from the nozzle 31, 32, 41, 42 and the center area C flow generally along arrows shown in FIG. 18, so that the first reaction gas and the second reaction gas cannot be intermixed. Therefore, a proper MLD (or ALD) mode film deposition can be realized by such an arrangement.

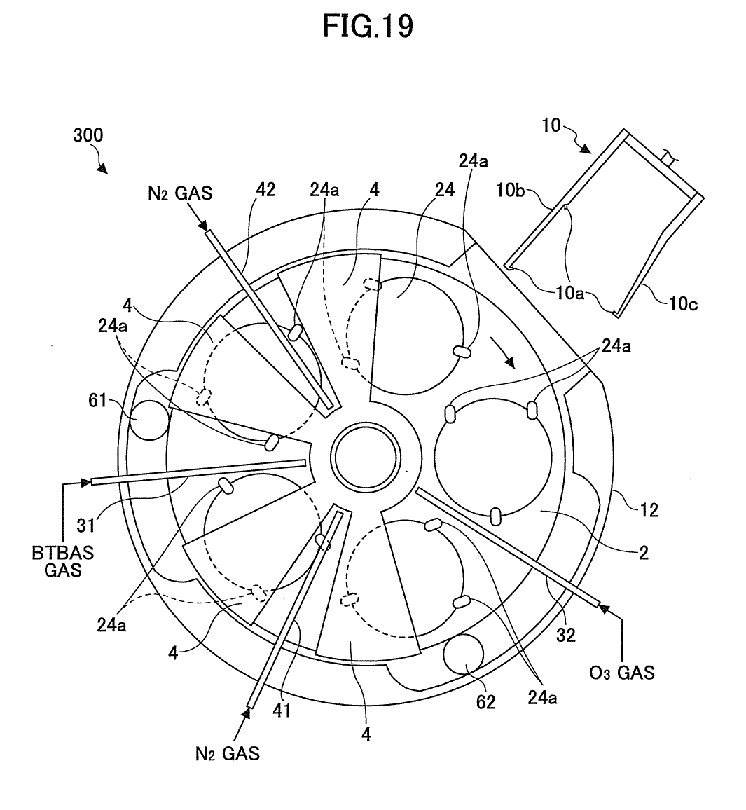

In addition, the separation area D may be configured by attaching two sector-shaped plates on the bottom surface of the ceiling plate 1 with screws so that the two sector-shaped plates are located one on each side of the separation gas nozzle 41 (42), as stated above. FIG. 19 is a plan view of such a configuration. In this case, the distance between the convex portion 4 and the separation gas nozzle 41 (42), and the size of the convex portion 4 can be determined taking into consideration ejection rates of the separation gas and the reaction gas in order to effectively demonstrate the separation function of the separation area D.

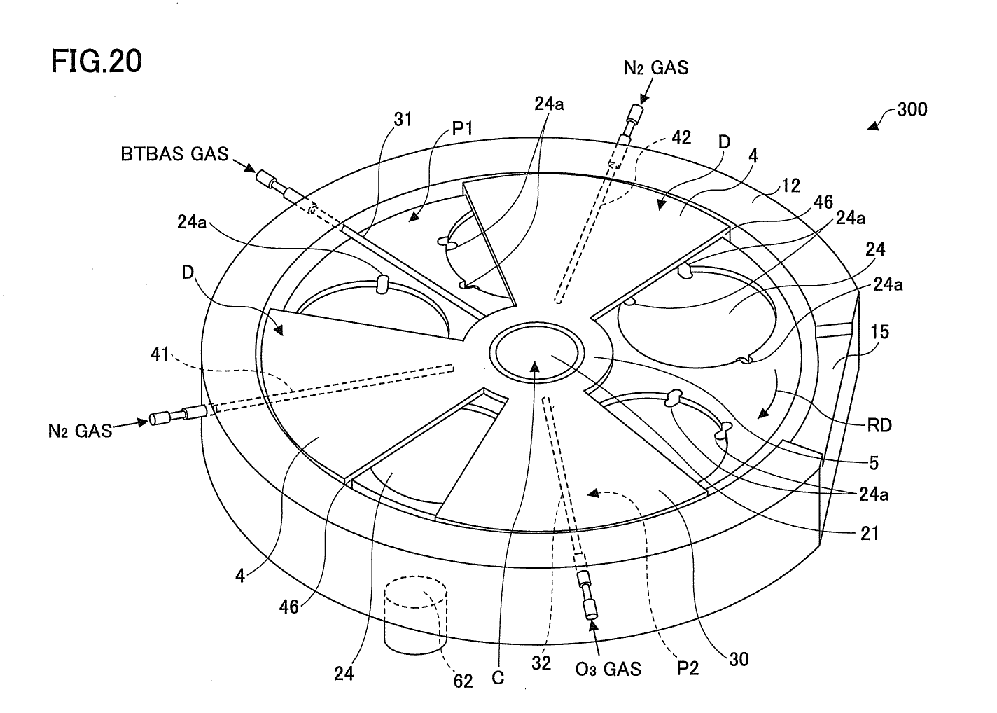

In the above embodiment, the first process area P1 and the second process area 22 correspond to the areas having the ceiling surface 45 higher than the ceiling surface 44 of the separation area D. However, at least one of the first process area P1 and the second process area P2 may have another ceiling surface that opposes the susceptor 2 in both sides of the reaction gas supplying nozzle 31 (32) and is lower than the ceiling surface 45 in order to prevent gas from flowing into a gap between the ceiling surface concerned and the susceptor 2. This ceiling surface, which is lower than the ceiling surface 45, may be as low as the ceiling surface 44 of the separation area D. FIG. 20 shows an example of such a configuration. As shown, a sector-shaped convex portion 30 is located in the second process area P2, where O₃ gas is adsorbed on the wafer W, and the reaction gas nozzle 32 is located in the groove portion (not shown) formed in the convex portion 30. In other words, this second process area P2 shown in FIG. 20 is configured in the same manner as the separation area D, while the gas nozzle is used in order to supply the reaction gas. In addition, the convex portion 30 may be configured as a hollow convex portion, an example of which is illustrated in the subsections (a) through (c) of FIG. 16.

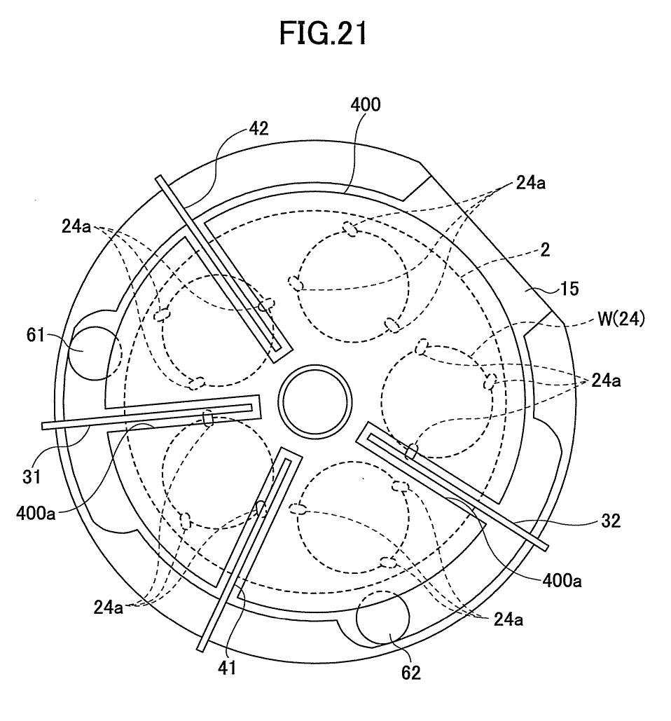

Moreover, the ceiling surface, which is lower than the ceiling surface 45 and as low as the ceiling surface 44 of the separation area D, may be provided for both reaction gas nozzles 31, 32 and extended to reach the ceiling surfaces 44 in other embodiments, as shown in FIG. 21, as long as the low ceiling surfaces 44 are provided on both sides of the reaction gas nozzle 41 (42). In other words, another convex portion 400 may be attached on the bottom surface of the ceiling plate 11, instead of the convex portion 4. Referring to FIG. 21, the convex portion 400 has the shape of a substantially circular plate, opposes substantially the entire upper surface of the susceptor 2, has four slots 400a where the corresponding gas nozzles 31, 32, 41, 42 are housed, the slots 400a extending in a radial direction, and leaves a thin space below the convex portion 400 in relation to the susceptor 2. A height of the thin space may be comparable with the height h stated above. When the convex portion 400 is employed, the reaction gas ejected from the reaction gas nozzle 31 (32) spreads to both sides of the reaction gas nozzle 31 (32) below the convex portion 400 (or in the thin space) and the separation gas ejected from the separation gas nozzle 41 (42) diffuses to both sides of the separation gas nozzle 41 (42). The reaction gas and the separation gas flow into each other in the thin space and are evacuated through the evacuation port 61 (62). Even in this case, the reaction gas ejected from the reaction gas nozzle 31 cannot be intermixed with the other reaction gas ejected from the reaction gas nozzle 32, thereby realizing a proper MLD (or ALD) mode film deposition.

Incidentally, the convex portion 400 may be configured by combining the hollow convex portions 4 shown in any section of FIG. 16 in order to eject the reaction gases and the separation gases from the corresponding ejection holes 33 in the corresponding hollow convex portions 4 without using the gas nozzles 31, 32, 41, 42 and the slits 400a.

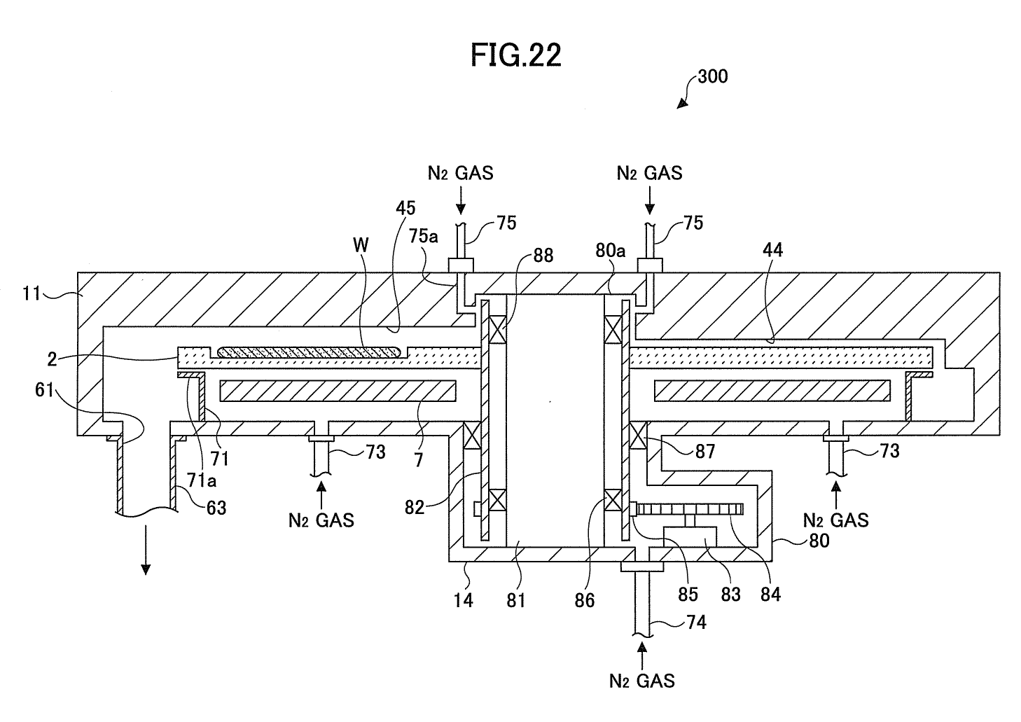

In the above embodiments, the rotational shaft 22 for rotating the susceptor 2 is located in the center portion of the vacuum chamber 1. In addition, the space 52 between the core portion 21 and the ceiling plate 11 is purged with the separation gas in order to prevent the reaction gases from being intermixed through the center portion. However, the vacuum chamber 1 may be configured as shown in FIG. 22 in other embodiments. Referring to FIG. 22, the bottom portion 14 of the chamber body 12 has a center opening to which a housing case 80 is hermetically attached. Additionally, the ceiling plate 11 has a center concave portion 80a. A pillar 81 is placed on the bottom surface of the housing case 80, and a top end portion of the pillar 81 reaches a bottom surface of the center concave portion 80a. The pillar 81 can prevent the first reaction gas (BTBAS) ejected from the first reaction gas nozzle 31 and the second reaction gas (O₃) ejected from the second reaction gas nozzle 32 from being intermixed through the center portion of the vacuum chamber 1.

In addition, a rotation sleeve 82 is provided so that the rotation sleeve 82 coaxially surrounds the pillar 81. The rotation sleeve 82 is supported by bearings 86, 88 attached on an outer surface of the pillar 81 and a bearing 87 attached on an inner side wall of the housing case 80. Moreover, the rotation sleeve 82 has a gear portion 85 formed or attached on an outer surface of the rotation sleeve 82. Furthermore, an inner circumference of the ring-shaped susceptor 2 is attached on the outer surface of the rotation sleeve 82. A driving portion 83 is housed in the housing case 80 and has a gear 84 attached to a shaft extending from the driving portion 83. The gear 84 is meshed with the gear portion 85. With such a configuration, the rotation sleeve 82 and thus the susceptor 2 are rotated by the driving portion 83.

A purge gas supplying pipe 74 is connected to an opening formed in a bottom of the housing case 80, so that a purge gas is supplied into the housing case 80. With this, an inner space of the housing case 80 may be kept at a higher pressure than an inner space of the chamber 1, in order to prevent the reaction gases from flowing into the housing case 80. Therefore, no film deposition takes place in the housing case 80, thereby reducing maintenance frequency. In addition, purge gas supplying pipes 75 are connected to corresponding conduits 75a that reach from an upper outer surface of the chamber 1 to an inner side wall of the concave portion 80a, so that a purge gas is supplied toward an upper end portion of the rotation sleeve 82. Because of the purge gas, the BTBAS gas and the O₃ gas cannot be mixed through a space between the outer surface of the rotation sleeve 82 and the side wall of the concave portion 80a. Although the two purge gas supplying pipes 75 are illustrated in FIG. 22, the number of the pipes 75 and the corresponding conduits 75a may be determined so that the purge gas from the pipes 75 can assuredly prevent gas mixture of the BTBAS gas and the O₃ gas in and around the space between the outer surface of the rotation sleeve 82 and the side wall of the concave portion 80a.

In the embodiment illustrated in FIG. 22, a space between the side wall of the concave portion 80a and the upper end portion of the rotation sleeve 82 corresponds to the ejection hole for ejecting the separation gas. In addition, the center area located at a center portion of the vacuum chamber 1 is configured with the ejection hole, the rotation sleeve 82, and the pillar 81.

Although the two kinds of reaction gases are used in the film deposition apparatus 300 according to the above embodiment, three or more kinds of reaction gases may be used in other film deposition apparatuses according to other embodiments of the present invention. In this case, a first reaction gas nozzle, a separation gas nozzle, a second reaction gas nozzle, a separation gas nozzle, and a third reaction gas nozzle may be located in this order at predetermined angular intervals, each nozzle extending along the radial direction of the susceptor 2. Additionally, the separation areas D including the corresponding separation gas nozzles are configured the same as explained above.

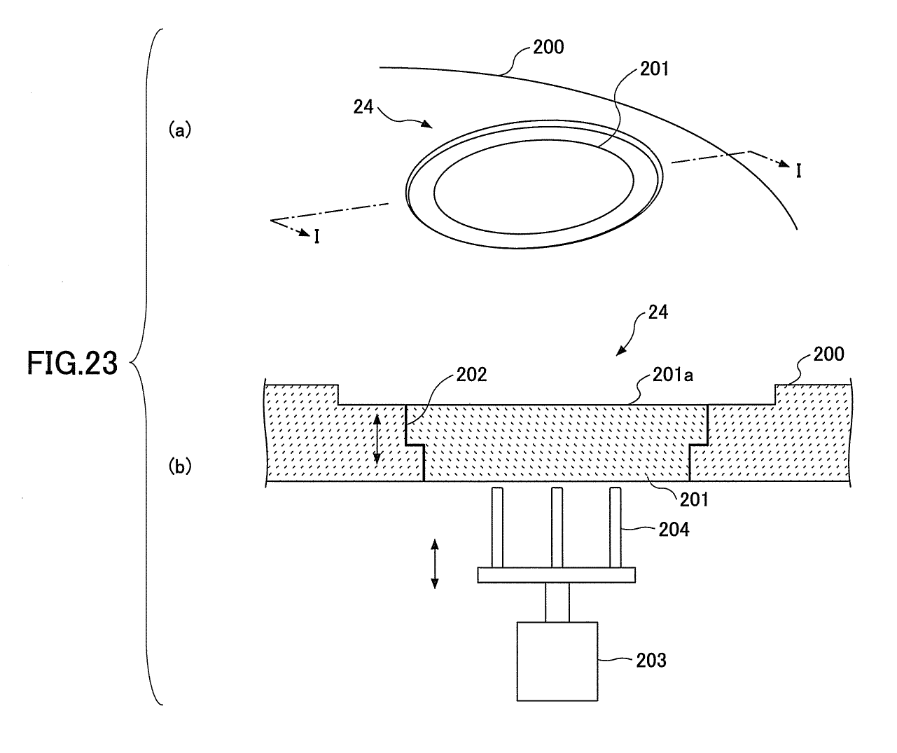

Moreover, the film deposition apparatus 300 according to this embodiment of the present invention may have a susceptor 200 (FIG. 23) in place of the susceptor 2. The susceptor 200 is different from the susceptor 2 in that the susceptor 200 does not have the concave portions 24a (FIG. 3) formed in the susceptor 2, but has a susceptor plate 201 in a substantial center of the wafer receiving portion 24 having a circular concave shape, while the susceptor 200 is the same as the susceptor 2 in other configuration details such as the size, the number of the wafer receiving portions 24, and the like.

The susceptor plate 201 has a circular top view shape and is arranged concentrically to the wafer receiving portion 24. The susceptor plate 201 may have a diameter about 4 mm through about 10 mm smaller than the diameter of the wafer W. The susceptor plate 201 has a T-shaped cross-sectional shape, as shown in a subsection (b) of FIG. 23, which is a cross-sectional view taken along an I-I line in a subsection (a) of FIG. 23, and is tightly fitted into a stepped opening 202 that goes through the wafer receiving portion 24 of the susceptor 200. With this, the susceptor plate 201 contacts the susceptor 2 with a larger outer circumferential surface, an annular reverse surface in parallel with the upper surface of the susceptor plate 201 (the wafer receiving portion 24), and a smaller outer circumferential surface. Because plural surfaces, especially the annular reverse surface in parallel with the upper surface of the susceptor plate 201, contact the susceptor 200, in addition to the susceptor plate 201 being tightly fitted into the susceptor 200 (the opening 202), even when a purge gas is supplied to, for example, the lower surface of the susceptor 200 (the surface without the wafer receiving portion 24), the purge gas is prevented from flowing from the lower surface side to the upper surface side of the susceptor 200. Accordingly, problems of wafer slippage in the wafer receiving portion and degradation of the temperature uniformity across the wafer, which may originate from the purge gas supplied toward the lower surface of the susceptor 200, are not caused in the film deposition apparatus 300 provided with the susceptor 200.

Referring to the subsection (b) of FIG. 23, a driving apparatus 203 is provided below the susceptor plate 201. Supporting rods 204 are attached on an upper portion of the driving apparatus 203. The supporting rods 204 are arranged at equal angular intervals of about 120°, for example, along a same circle. When the supporting rods 204 are moved upward by the driving apparatus 203, the susceptor plate 201 is pushed upward by the supporting rods 204, and when the supporting rods 204 move downward, the susceptor plate 201 moves downward accordingly and is fitted into the stepped opening 202. In addition, when the susceptor plate 201 is positioned at the lowest height, or fitted into the opening 202, an upper surface 201a of the susceptor plate 201 and an upper surface of the wafer receiving portion 24, which does not include the susceptor plate 201, form one plane surface. Therefore, the entire lower surface of the wafer W contacts the upper surface of the wafer receiving portion 24 (including the susceptor plate 201), and thus the preferred temperature uniformity across the wafer W is maintained.

Incidentally, the driving apparatus 203 and the supporting rods 204 are located below the wafer receiving portion 24 that is aligned with the transfer opening 15 of the vacuum chamber 1. In addition, the supporting rods 204 are arranged so that they are not disturbed by the heater unit 7 located below the susceptor 200. For example, when the heater unit 7 includes plural annular heater elements, the supporting rods 204 can move upward/downward through a space between the annular heater elements to reach the lower surface of the susceptor plate 201.

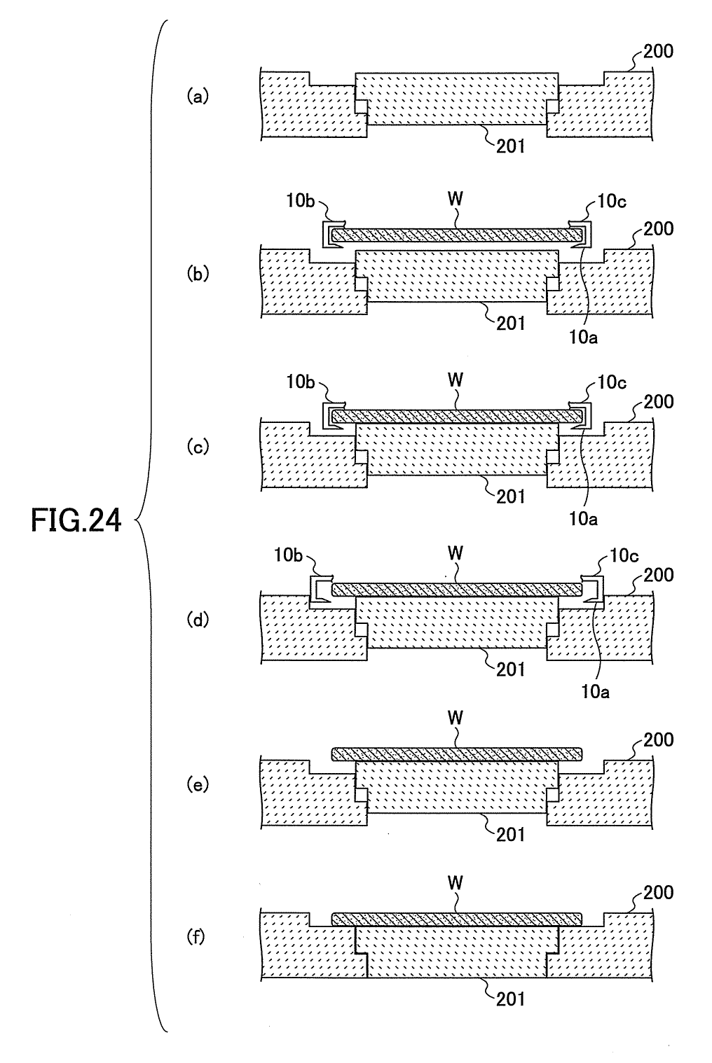

Next, operations of transferring the wafer W onto the susceptor 200 by the transfer arm 10 is explained with reference to FIG. 24. In FIG. 24, the supporting rods 204 and the driving apparatus 203 are omitted for simplicity of illustration.

First, when one of the wafer receiving portions 24 having the susceptor plate 201 is aligned to the transfer opening 15, the susceptor 201 is raised, which forms a step between the upper surface of the susceptor plate 201 and the upper surface of the wafer receiving portion 24, which does not include the upper surface of the susceptor plate 201 (a subsection (a) of FIG. 24).

Next, the transfer arm 10 holding the wafer W enters the vacuum camber 1 (FIG. 1) and holds the wafer W above the wafer receiving portion 24 (susceptor plate 201) (a subsection (b) of FIG. 24). As shown, the wafer W is supported from its lower surface by the claws 10a of the transfer arm 10.

Subsequently, when the transfer arm 10 moves downward, the lower surface of the wafer W contacts the upper surface of the susceptor plate 201, so that the claws 10a separate from the lower surface of the wafer W (a subsection (c) of FIG. 24). Next, when the arm portions 10b, 10c of the transfer arm 10 move away from each other, the claws 10a are positioned outside the edge of the wafer W (a subsection (d) of FIG. 24). Then, the transfer arm 10 moves upward, and is pulled away from the vacuum chamber 1 (a subsection (e) of FIG. 24). Finally, the susceptor plate 201 moves downward and is fitted into the opening 202 (a subsection (f) of FIG. 24).

When the above procedures are carried out for all the wafer receiving portions 24 of the susceptor 200, all the wafers W are placed in the wafer receiving portions 24. In addition, when the wafers W are removed from the susceptor 200, operations opposite to the above transfer-in procedures are carried out.

As explained above, because the susceptor plate 201 moves upward, leaving the step between the upper surface of the susceptor plate 201 and the upper surface of the wafer receiving portion 24, which does not include the upper surface of the susceptor plate 201, the step is used in transferring the wafer W from the claws 10a of the transfer arm 10 to the susceptor plate 201 and then to the wafer receiving portion 24.

Incidentally, the top view shape of the susceptor plate 201 is not limited to a circle, but may be an ellipse, a square, a rectangle, or a triangle, as long as the susceptor plate 201 allows the claws 10a of the transfer arm 10 to move lower than the upper surface of the susceptor plate 201.

In addition, the cross-sectional shape of the susceptor plate 201 is not limited to a T-shape, but may be an inverted triangle. Namely, a side surface of the susceptor plate 201 may be inclined with respect to the upper surface of the susceptor plate 201. In this case, the opening 202 of the susceptor 200 has to have an inverted cone shape where a diameter of the inner circumferential surface of the opening 202 becomes smaller along a downward direction. Even with such a configuration, the purge gas supplied to the lower surface of the susceptor 200 cannot flow from the lower surface side to the upper surface side of the susceptor 200 through a boundary between the susceptor plate 201 and the opening 202 of the susceptor 200. Moreover, the stepped opening 202 explained above may have an annular groove in a surface in parallel with the upper surface of the susceptor 200, and the susceptor plate 201 may have, in the reverse surface thereof, an annular protruding portion that can be fitted into the groove portion. With this, the purge gas is certainly prevented from flowing from the lower surface side to the upper surface side of the susceptor 200 through a boundary between the susceptor plate 201 and the stepped opening 202 of the susceptor 200.

In addition, when the susceptor 200 is used, the transfer arm 10 is not necessarily movable upward/downward. Namely, when the susceptor plate 201 moves upward until the claws 10a of the transfer arm 10 are positioned lower than the upper surface of the susceptor plate 201, the wafer W can be transferred from the transfer arm 10 to the susceptor plate 201.

Moreover, while the transfer arm 10 is configured such that the arm portions 10b, 10c can move closer to and away from each other in order to support and release the wafer W, respectively, in the above embodiment, the arm portions 10b, 10c may be rotated around longitudinal directions of the arm portions 10b, 10c in opposite rotation directions. Specifically, while the arm portions 10b, 10c move away from each other, similar to a case shown in the subsection (c) of FIG. 10, the arm portion 10b may rotate counter-clockwise around the longitudinal direction thereof, and the arm portion 10c may rotate clockwise around the longitudinal direction thereof, so that the arm portions 10b, 10c are positioned outside the edge of the wafer W. In this case, the arm portions 10b, 10c and the claws 10a may be altered in terms of their shapes so that they do not touch the wafer W.

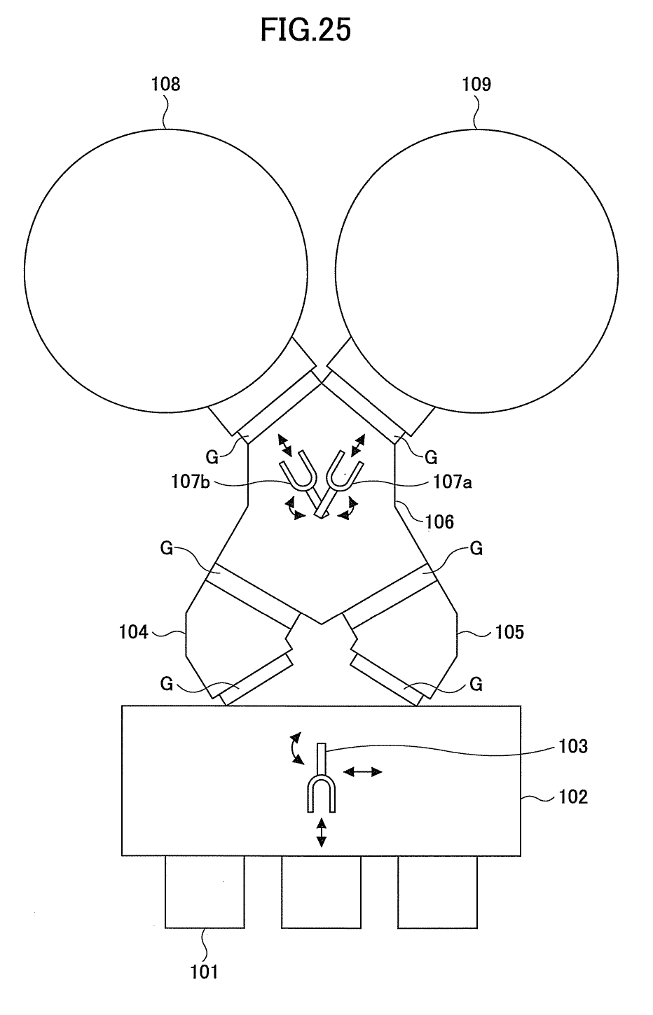

The film deposition apparatus 300 according to embodiments of the present invention may be integrated into a wafer process apparatus, an example of which is schematically illustrated in FIG. 25. The wafer process apparatus includes an atmospheric transfer chamber 102 in which a transfer arm 103 is provided, a load lock chamber (preparation chamber) 105 whose atmosphere is changeable between vacuum and atmospheric pressure, a vacuum transfer chamber 106 in which two transfer arms 107a, 107b are provided, and film deposition apparatuses 108, 109 according to embodiments of the present invention. In addition, the wafer process apparatus includes cassette stages (not shown) on which a wafer cassette 101 such as a Front Opening Unified Pod (FOUP) is placed. The wafer cassette 101 is brought onto one of the cassette stages, and connected to a transfer in/out port provided between the cassette stage and the atmospheric transfer chamber 102. Then, a lid of the wafer cassette (FOUP) 101 is opened by an opening/closing mechanism (not shown) and the wafer is taken out from the wafer cassette 101 by the transfer arm 103. Next, the wafer is transferred to the load lock chamber 104 (105). After the load lock chamber 104 (105) is evacuated, the wafer in the load lock chamber 104 (105) is transferred further to one of the film deposition apparatuses 108, 109 through the vacuum transfer chamber 106 by the transfer arm 107a (107b) . In the film deposition apparatus 108 (109), a film is deposited on the wafer in such a manner as described above. Because the wafer process apparatus has two film deposition apparatuses 108, 109 that can house five wafers at a time, the MLD (or ALD) mode deposition can be performed at high throughput.

Incidentally, although the MLD film deposition apparatus is explained as an embodiment of the present invention, the present invention may be applied to various film deposition apparatuses, regardless of kinds of deposited films (an insulation film, a conductive film (a metal film) and the like), or classification of a chemical deposition and a physical deposition.

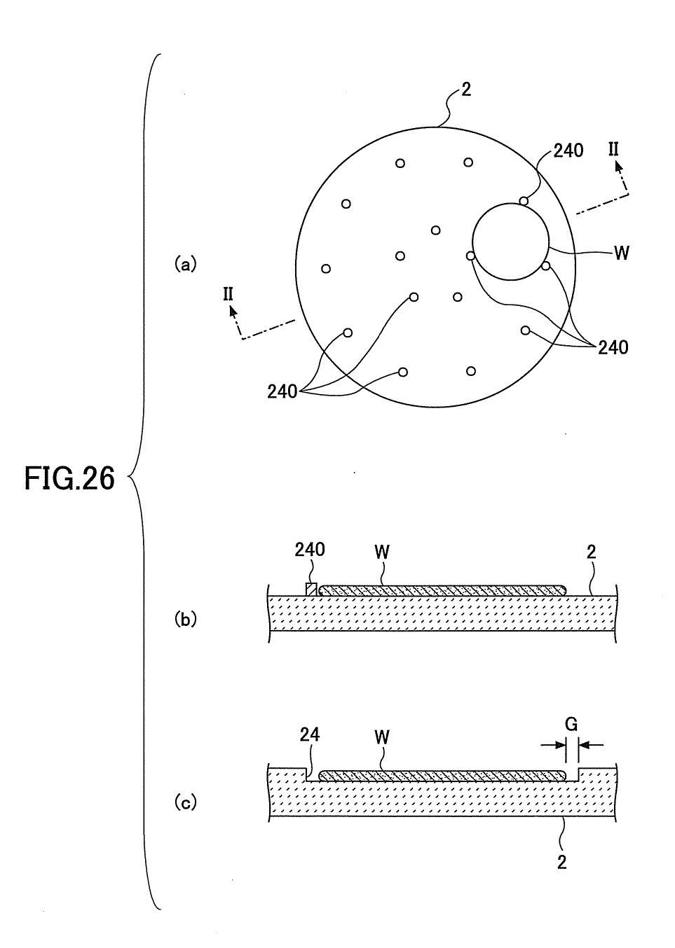

In addition, while the wafer receiving portion 24 of the susceptors 2, 200 has a circular concave shape, the wafer receiving portion 24 may be defined by at least three positioning pins 240 as shown in a subsection (a) of FIG. 26 without forming a circular concavity in the susceptors 2, 200. When the wafer receiving portion 24 is configured to include the circular concavity, a gap (clearance) G is formed between the wafer W and the inner circumferential surface of the circular concavity, as shown in a subsection (c) of FIG. 26. Such a gap G may affect the thickness uniformity of the film deposited on the wafer W, depending on the width of the gap G. However, according to the positioning pins 240, the gap G is not formed, so that the thickness uniformity is not affected. Incidentally, although not illustrated, the wafer receiving portion 24 defined by the positioning pins 240 has to be provided with the concave portions 24a that allow the claws 10a of the transfer arm 10, which support the wafer W from the lower surface of the wafer W, to enter.

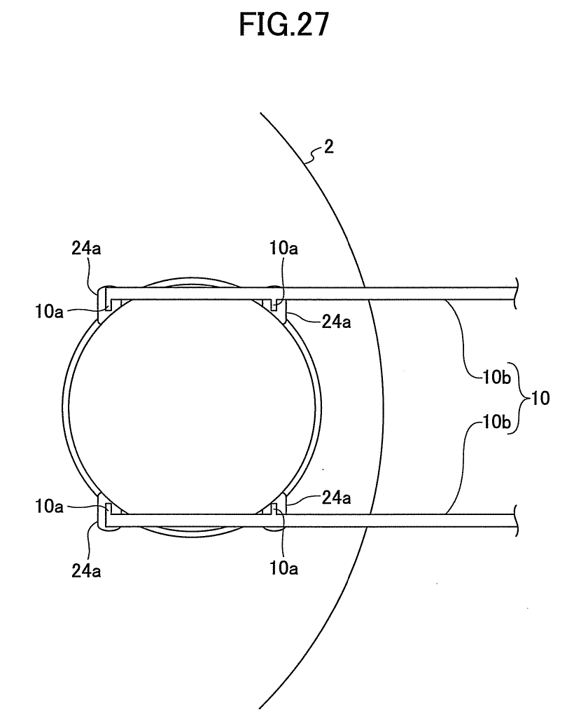

Moreover, while the transfer arm 10 has the three claws 10a in the above embodiments, the number of the claws 10a is not limited to three, but may be arbitrarily altered. For example, the transfer arm 10 may have the two transfer arms 10b having the two claws 10a (10a1, 10a2), as shown in FIG. 27. With such a configuration, the wafer W is supported by a total of four claws 10a. In this case, the claws 10a do not necessarily extend toward the center of the wafer W, but extend in a direction perpendicular to the longitudinal direction of the arm portion 10b. Even with this, the transfer arm 10 can certainly transfer the wafer W.

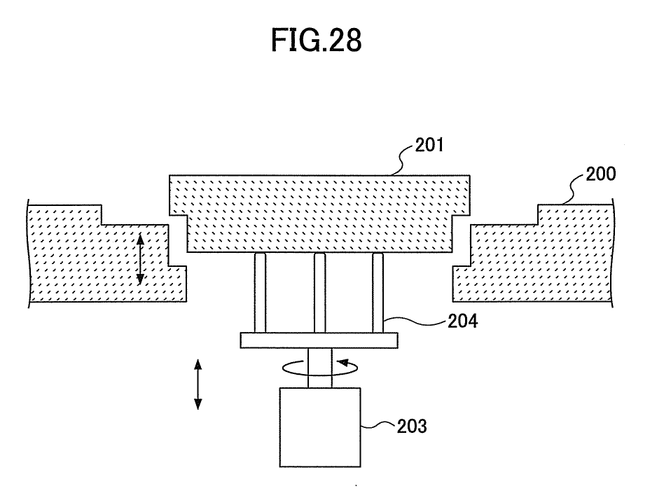

Furthermore, as shown in FIG. 28, the driving apparatus 203 may be configured not only to move the three supporting rods 204 upward/downward but also to be able to rotate the supporting rods 204. When the driving apparatus 203 is so configured and, for example, in the lower surface of the susceptor plate 201 are provided three concave portions into which the three supporting rods 204 are fitted, respectively, the susceptor plate 201 can be rotated during the film deposition process. With this, the wafer W may move in a planetary manner by orbital rotation of the wafer receiving portion 24 due to the rotation of the susceptor 200 and rotation of the susceptor plate 201 itself, thereby improving the across-wafer uniformity of the film on the wafer W. In addition, after the film deposition is completed, the wafer W may be rotated so that an orientation flat or a notch of the wafer W is directed to a predetermined direction when the wafer W is raised by the susceptor plate 201. With this, the wafers W may be housed in the wafer cassette 101 with the orientation flat or the notch directed to the same direction, which can eliminate alignment procedures in the subsequent process.

While the present invention has been explained with reference to the foregoing embodiments, the present invention is not limited to the disclosed embodiments, but may be modified or altered within the scope of the accompanying claims.

What is claimed is:

1. A film deposition apparatus for depositing a film on a substrate by carrying out a cycle of alternately supplying at least two kinds of reaction gases that react with each other to the substrate to produce a layer of a reaction product in a chamber, the film deposition apparatus comprising:
a transfer arm including a claw portion for supporting a lower peripheral surface portion of the substrate, wherein the transfer arm is movable into and out from the chamber;
a susceptor rotatably provided in the chamber, wherein the susceptor includes a substrate receiving portion provided, in one surface of the susceptor, for the substrate to be placed in, and a step portion provided to allow the claw portion to move to a position lower than an upper surface of the substrate receiving portion;
a first reaction gas supplying portion configured to supply a first reaction gas to the one surface;
a second reaction gas supplying portion configured to supply a second reaction gas to the one surface, wherein the second reaction gas supplying portion is separated from the first reaction gas supplying portion along a rotation direction of the susceptor;
a separation area located along the rotation direction between a first process area in which the first reaction gas is supplied and a second process area in which the second reaction gas is supplied;
a center area that is located substantially in a center portion of the chamber in order to separate the first process area and the second process area, and has an ejection hole that ejects a first separation gas along the one surface; and
an evacuation opening provided in the chamber in order to evacuate the chamber;
wherein the separation area includes a separation gas supplying portion that supplies a second separation gas, and a ceiling surface that creates in relation to the one surface of the susceptor a thin space in which the second separation gas may flow from the separation area to the process area side in relation to the rotation direction.

2. The film deposition apparatus of claim 1, wherein the step portion is formed of a concave portion made in the susceptor.

3. The film deposition apparatus of claim 1, wherein the susceptor includes a susceptor plate whose upper surface constitutes a part of the substrate receiving portion, the susceptor plate being movable upward, and
wherein the step portion is formed in such a manner that the susceptor plate is movable upward.

4. The film deposition apparatus of claim 3, wherein the susceptor plate includes a surface that crosses a direction perpendicular to an upper surface of the susceptor plate, and
wherein the susceptor plate contacts the susceptor with the surface.

5. The film deposition apparatus of claim 1, wherein the claw portions extend in a direction toward a center of the substrate when the claw portions support a lower peripheral surface portion of the substrate.

6. A semiconductor device fabrication apparatus, comprising:
a chamber where a predetermined process is carried out with respect to a substrate;
a transfer arm that includes claw portions for supporting a lower peripheral surface portion of the substrate and that moves into and out from the chamber; and
a susceptor that includes a substrate receiving portion in which the substrate is placed, and a step portion provided to allow the claw portions to move to a position lower than an upper surface of the substrate receiving portion.

7. The semiconductor device fabrication apparatus of claim 6, wherein the step portion is formed of a concave portion made in the susceptor.

8. The semiconductor device fabrication apparatus of claim 6, wherein the susceptor includes a susceptor plate whose upper surface constitutes a part of the substrate receiving portion, the susceptor plate being movable upward, and
wherein the step portion is formed in such a manner that the susceptor plate is movable upward.

9. The semiconductor device fabrication apparatus of claim 8, wherein the susceptor plate includes a surface that crosses a direction perpendicular to an upper surface of the susceptor plate, and
wherein the susceptor plate contacts the susceptor with the surface.

10. The semiconductor device fabrication apparatus of claim 6, wherein the claw portions extend in a direction toward a center of the substrate when the claw portions support a lower peripheral surface portion of the substrate.

11. A susceptor on which a substrate subject to a predetermined process in a semiconductor device fabrication apparatus is placed, the susceptor comprising:
a substrate receiving portion on which the substrate is placed; and
a step portion provided to allow a claw portion of a substrate transport arm to move to a position lower than an upper surface of the susceptor, the claw portion supporting a lower peripheral surface portion of the substrate.

12. The susceptor of claim 11, wherein the step portion is formed of a concave portion made in the susceptor.

13. The susceptor of claim 11, wherein the susceptor includes a susceptor plate whose upper surface constitutes a part of the substrate receiving portion, the susceptor plate being movable upward, and
wherein the step portion is formed in such a manner that the susceptor plate is movable upward.

14. The susceptor of claim 13, wherein the susceptor plate includes a surface that crosses a direction perpendicular to an upper surface of the susceptor plate, and
wherein the susceptor plate contacts the susceptor with the surface.

15. The susceptor of claim 11, wherein the claw portion extends in a direction toward a center of the substrate when the claw portion supports a lower peripheral surface portion of the substrate.

16. A film deposition method for depositing a film on a substrate by carrying out a cycle of alternately supplying at least two kinds of reaction gases that react with each other to the substrate to produce a layer of a reaction product in a chamber, the film deposition method comprising steps of:
supporting a lower peripheral surface portion of the substrate with a claw portion provided in a transfer arm and transferring the substrate into the chamber with the transfer arm;
placing the substrate on a susceptor by using a step portion of the susceptor to move the claw portion to a position lower than an upper surface of a substrate receiving portion, wherein the susceptor is rotatably provided in the chamber, and includes the substrate receiving portion, in one surface of the susceptor, for the substrate to be placed in, and the step portion provided to allow the claw portion of the transfer arm to move to a position lower than the upper surface of the substrate receiving portion;
rotating the susceptor on which the substrate is placed;
supplying a first reaction gas from a first reaction gas supplying portion to the susceptor;
supplying a second reaction gas from a second reaction gas supplying portion to the susceptor, the second reaction gas supplying portion being separated from the first reaction gas supplying portion along a rotation direction of the susceptor;
supplying a first separation gas from a separation gas supplying portion provided in a separation area located between a first process area in which the first reaction gas is supplied from the first reaction gas supplying portion and a second process area in which the second reaction gas is supplied from the second reaction gas supplying portion, in order to flow the first separation gas from the separation area to the process area relative to the rotation direction of the susceptor in a thin space created between a ceiling surface of the separation area and the susceptor;
supplying a second separation gas from an ejection hole formed in a center area located in a center portion of the chamber; and
evacuating the chamber.

17. The film deposition method of claim 16, wherein the susceptor includes a susceptor plate whose upper surface constitutes a part of the substrate receiving portion, the susceptor plate being movable upward, and
wherein the step of placing the substrate includes a step of moving the susceptor plate upward to form the step portion.

18. A computer readable storage medium storing a program for causing a film deposition apparatus of claim 1 to perform a film deposition method for depositing a film on a substrate by carrying out a cycle of alternately supplying at least two kinds of reaction gases that react with each other to the substrate to produce a layer of a reaction product in a chamber, the film deposition method comprising steps of:
supporting a lower peripheral surface portion of the substrate with a claw portion provided in a transfer arm and transferring the substrate into the chamber with the transfer arm;
placing the substrate on a susceptor by using a step portion of the susceptor to move the claw portion to a position lower than an upper surface of a substrate receiving portion, wherein the susceptor is rotatably provided in the chamber, and includes the substrate receiving portion, in one surface of the susceptor, for the substrate to be placed in, and the step portion provided to allow the claw portion of the transfer arm to move to a position lower than the upper surface of the substrate receiving portion;
rotating the susceptor on which the substrate is placed;
supplying a first reaction gas from a first reaction gas supplying portion to the susceptor;
supplying a second reaction gas from a second reaction gas supplying portion to the susceptor, the second reaction gas supplying portion being separated from the first reaction gas supplying portion along a rotation direction of the susceptor;
supplying a first separation gas from a separation gas supplying portion provided in a separation area located between a first process area in which the first reaction gas is supplied from the first reaction gas supplying portion and a second process area in which the second reaction gas is supplied from the second reaction gas supplying portion, in order to flow the first separation gas from the separation area to the process area relative to the rotation direction of the susceptor in a thin space created between a ceiling surface of the separation area and the susceptor;
supplying a second separation gas from an ejection hole formed in a center area located in a center portion of the chamber; and
evacuating the chamber.
